(19) United States
(12) Patent Application Publication
(10) Pub. No.: US 2009/0050956 A1
(43) Pub. Date: Feb. 26, 2009

(54) SEMICONDUCTOR MEMORY DEVICE AND METHOD OF MANUFACTURING THE SAME

(75) Inventors: TETSUYA ISHIMARU, Tokyo (JP); YOSHIYUKI KAWASHIMA, Hitachinaka (JP); YASUHIRO SHIMAMOTO, Tokorozawa (JP); KAN YASUI, Kodaira (JP); TSUYOSHI ARIGANE, Akishima (JP); TOSHIYUKI MINE, Fussa (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/191,958

(22) Filed: Aug. 14, 2008

(30) Foreign Application Priority Data
Aug. 24, 2007 (JP) JP 2007-218498

(51) Int. Cl. H01L 29/792; H01L 21/336

(52) U.S. Cl. 257/324; 438/261; 257/E21.409; 257/E29.309

(57) ABSTRACT

In a memory cell including an nMIS for memory formed on the sides of an nMIS for select and an nMIS for select via dielectric films and a charge storage layer, the thickness of a gate dielectric under the gate longitudinal direction end of a select gate electrode is formed thicker than that of the gate dielectric under the gate longitudinal direction center and the thickness of the lower layer dielectric film that is positioned between the select gate electrode and the charge storage layer and is nearest to a semiconductor substrate is formed 1.5 times or below of the thickness of the lower layer dielectric film positioned between the semiconductor substrate and the charge storage layer.

### CROSS-REFERENCE TO RELATED APPLICATION

The present application claims priority from Japanese Patent Application No. JP 2007-218498 filed on Aug. 24, 2007, the content of which is hereby incorporated by reference into this application.

### TECHNICAL FIELD OF THE INVENTION

The present invention relates to a semiconductor memory device and a technology of manufacturing the same, in particular, to a technology effective when applied to a semiconductor memory device having an MONOS (Metal Oxide Nitride Oxide Semiconductor) memory cell in which a nitride film is a charge storage layer.

### BACKGROUND OF THE INVENTION

As a nonvolatile semiconductor memory device to which data can be written and erased electrically, an EEPROM (Electrical Erasable and Programmable Read Only Memory) is used now. In the memory cell of the nonvolatile semiconductor memory device represented by a flash memory, an charge accumulation region represented by a conductive floating gate electrode surrounded by an oxide film or a charge-trapping dielectric film is arranged under the gate electrode of an MIS (Metal Insulator Semiconductor), and an charge is accumulated in this charge accumulation region as memory information, and the same is read as the threshold voltage of the MIS transistor.

As the memory cell in which a charge-trapping dielectric film is a charge accumulation region, there is a memory cell of the MONOS method. In particular, a split gate type memory cell in which one memory cell includes two gate electrodes of a memory gate electrode and a select gate electrode is used widely in late years. Because the split gate type memory cell uses a charge-trapping dielectric film as its charge accumulation region, it can accumulate a charge discretely, and thereby it has superior reliability of the data retention. Further, because it has superior reliability of the data retention, the oxide films formed above and under the charge-trapping dielectric film can be made thin, therefore, it has advantages including the low voltage of program/erase operations and the like. Furthermore, by using split gate type memory cell, hot electrons can be injected into the charge-trapping dielectric film by SSI (Source Side Injection) method whose injection efficiency is excellent, and data can be written at a high speed and at a low current. Moreover, it has the advantage that peripheral circuits can be made small because the control of its program and erase operations is simple. The charge-trapping dielectric film is a dielectric film enabling charge accumulation, and, as an example, there is a silicon nitride film.

The cell structure of the split gate type memory cell is roughly divided into two kinds shown in FIGS. 35 and 36. In the first memory cell of the cell structure shown in FIG. 35, a select gate electrode CG is formed first, and an ONO film comprising a lower part oxide film OIb, a silicon nitride film NI, and an upper part oxide film OIt is formed, and a memory gate electrode MG is formed into the shape of a sidewall spacer (for example, refer to Japanese Patent Application Laid-Open Publication No. 2005-123518 (Patent Document 1)). In contrast, in the second memory cell of the cell structure shown in FIG. 36, an ONO film comprising a lower part oxide film OIb, a silicon nitride film NI and an upper part oxide film OIt is formed and the memory gate electrode MG is formed thereon, and then, a sidewall oxide film GAP to secure the withstand voltage between a memory gate electrode MG and a select gate electrode CG, and a gate dielectric OG of the select gate electrode CG are formed. Thereafter, the select gate electrode CG is formed into the shape of a sidewall spacer.

An advantage of the above first memory cell is that because there is the ONO film between the memory gate electrode MG and the select gate electrode CG, it is easy to secure the withstand voltage between the memory gate electrode MG and the select gate electrode CG, and the distance between them can be made as short as the thickness of the ONO film. Since the distance between the memory gate electrode MG and the select gate electrode CG can be made short, the gap resistance of the channel region under an interval between the memory gate electrode MG and the select gate electrode CG becomes small, and it is possible to obtain a larger read current than that in the above second memory cell. Meanwhile, in FIGS. 35 and 36, codes SUB, PW, Srm and Drm indicate a semiconductor substrate, a p well, a source region, and a drain region respectively.

When program is performed by the SSI method, in the split gate type MONOS memory cell, a program disturb becomes a problem. The program disturb herein is a phenomenon in which when a certain memory cell is selected, and the memory cell is programmed, the voltage applied to the selected memory cell is also applied to unselected memory cells that are connected to the same wire and are not selected, and the unselected memory cells perform weak program and weak erase operations, and data is lost slowly. In the program by the SSI method, a high voltage is applied to both the source line to which source regions of a plurality of memory cells are connected, and the memory gate line to which memory gate electrodes of a plurality of memory cells are connected. Therefore, there are unselected memory cells to which the high voltage of program is applied in both the source regions and the memory gate electrodes, and in the unselected memory cells, weak program in which electrons are injected into the charge accumulation region occurs, which becomes a problem.

As a method to solve the disturb, there is a method to reduce the number of memory cells to be connected to the same source line and the same memory gate line. However, in this method, it is necessary to divide one line into a plurality of lines, and increase the numbers of drivers to drive the lines, therefore, the area of memory module increases.

An object of the present invention is to provide a technology that can improve disturb tolerance at the time of program by the SSI method in a split gate type MONOS memory cell.

The above and other objects and novel characteristics of the present invention will be apparent from the description of this specification and the accompanying drawings.

### SUMMARY OF THE INVENTION

The typical ones of the inventions disclosed in this application will be briefly described as follows.

According to the present invention, there is provided a semiconductor memory device having a split gate type MONOS memory cell, including a select gate electrode of a field effect transistor for selection, a memory gate electrode of a field effect transistor for memory, a gate dielectric formed between a semiconductor substrate and the select gate electrode, a lower layer dielectric film formed between the semiconductor substrate and the memory gate electrode and between the select gate electrode and the memory gate electrode, a charge holding dielectric film of a laminating structure comprising a charge storage layer and an upper layer dielectric film, wherein the thickness of the gate dielectric under the gate longitudinal direction end of the select gate electrode is thicker than the thickness of the gate dielectric under the gate longitudinal center of the select gate electrode, and the thickness of the lower layer dielectric film that is positioned between the select gate electrode and the charge storage layer and is nearest to the semiconductor substrate, is 1.5 times or below of the thickness of the lower layer dielectric film between the semiconductor substrate and the charge storage layer.

According to the present invention, there is provided a method of manufacturing a semiconductor memory device having a split gate type MONOS memory cell, including a step of forming a gate dielectric of a field effect transistor for selection on the main surface of a semiconductor substrate, a step of forming a select gate electrode of a field effect transistor for selection comprising a first conductive film on the gate dielectric, a step of removing the gate dielectric in other regions than the gate dielectric under a select gate electrode, a step of performing an oxidation process to the semiconductor substrate, and, by performing oxidization process to a semiconductor substrate, forming the thickness of the gate dielectric under the gate longitudinal direction end of the select gate electrode thicker than that of the gate dielectric under the gate longitudinal center of the select gate electrode, a step of exposing the main surface of the semiconductor substrate while leaving the gate dielectric under the select gate electrode, a step of forming a lower layer dielectric film on the main surface of the semiconductor substrate, a step of forming a charge storage layer on the lower layer dielectric film, a step of forming an upper layer dielectric film on the charge storage layer, a step of forming a memory gate electrode of a field effect transistor for memory comprising a second conductive film on the side surface of the select gate electrode, a step of removing the memory gate electrode formed on one side of the select gate electrode, and a step of removing other lower layer dielectric film, the charge storage layer and the upper layer dielectric film than the lower layer dielectric film, the charge storage layer and the upper layer dielectric film between the select gate electrode and the memory gate electrode, and between the memory gate electrode and the semiconductor substrate, the charge storage layer and the upper layer dielectric film.

The effects obtained by typical aspects of the present invention will be briefly described below.

In a split gate type MONOS memory cell, it is possible to improve the disturb tolerance at the time of program by the SSI method, without reducing a read current. Further, because the disturb tolerance of the unselected memory cell is improved, it is possible to reduce the area of the memory module.

### BRIEF DESCRIPTIONS OF THE DRAWINGS

FIG. 1 is a cross sectional view showing a main part of a split gate type MONOS memory cell in which its channel is cut along the direction intersecting to its memory gate electrode according to a first embodiment of the present invention;

FIG. 2 is a cross sectional view showing an enlarged region A of FIG. 1;

FIG. 3 is a circuit diagram showing the array structure of the memory cell according to the first embodiment of the present invention;

FIG. 4 shows an example of the conditions of a voltage applied to the respective lines (the select gate lines, the memory gate line, the source lines, and the bit lines) at the time of program, erase, and read of the select cell according to the first embodiment of the present invention;

FIG. 5 shows an example of the conditions of a voltage applied to the respective terminals of the select cell and unselected cells at the time of information programming to the select cell according to the first embodiment of the present invention;

FIG. 6 is a cross sectional view of a main part of the memory cell to explain the actions of charge of program select memory cell according to the first embodiment of the present invention;

FIG. 7 is a graph showing the program characteristics of the memory cell according to the first embodiment of the present invention;

FIG. 8 is a graph showing the disturb characteristics according to the first embodiment of the present invention;

FIG. 9 is a graph showing the relation between the quantity of bird's beak of the gate dielectric under the gate longitudinal direction end of the select gate electrode and the disturb time at which the threshold voltage reaches −1V according to the first embodiment of the present invention;

FIG. 10 is a cross sectional view of a main part of the memory cell for explaining the mechanism of the electron injection at the time of the disturb according to the first embodiment of the present invention;

FIG. 11 is a graph showing the relation between the thickness of the lower layer dielectric film positioned between the select gate electrode and the charge storage layer and the maximum transconductance of the nMIS for memory according to the first embodiment of the present invention;

FIG. 12 is a cross sectional view showing a main part of the split gate type MONOS memory cell in the step of manufacturing according to the first embodiment of the present invention;

FIG. 13 is a cross sectional view showing the same main part as FIG. 12 in the step of the manufacture of the memory cell following FIG. 12;

FIG. 14 is a cross sectional view showing the same main part as FIG. 12 in the step of the manufacture of the memory cell following FIG. 13;

FIG. 15 is a cross sectional view showing the same main part as FIG. 12 in the step of the manufacture of the memory cell following FIG. 14;

FIG. 16 is a cross sectional view showing the same main part as FIG. 12 in the step of the manufacture of the memory cell following FIG. 15;

FIG. 17 is a graph showing the relation between the oxidation speed and the temperature of polycrystalline silicon film and single crystal silicon film according to the first embodiment of the present invention;

FIG. 18 is a cross sectional view showing the same main part as FIG. 12 in the step of the manufacture of the memory cell following FIG. 16;

FIG. 19 is a cross sectional view showing the same main part as FIG. 12 in the step of the manufacture of the memory cell following FIG. 18;

FIG. 20 is a cross sectional view showing the same main part as FIG. 12 in the step of the manufacture of the memory cell following FIG. 19;

FIG. 21 is a cross sectional view showing the same main part as FIG. 12 in the step of the manufacture of the memory cell following FIG. 20;

FIG. 22 is a cross sectional view showing an main part of a split gate type MONOS memory cell in the step of manufacturing according to a second embodiment of the present invention;

FIG. 23 is a cross sectional view showing the same main part as FIG. 22 in the step of the manufacture of the memory cell following FIG. 22;

FIG. 24 is a cross sectional view showing the same main part as FIG. 22 in the step of the manufacture of the memory cell following FIG. 23;

FIG. 25 is a cross sectional view showing a main part of a split gate type MONOS memory cell in the step of manufacturing according to a third embodiment of the present invention;

FIG. 26 is a cross sectional view showing the same main part as FIG. 25 in the step of the manufacture of the memory cell following FIG. 25;

FIG. 27 is a cross sectional view showing the same main part as FIG. 25 in the step of the manufacture of the memory cell following FIG. 26;

FIG. 28 is a cross sectional view showing the same main part as FIG. 25 in the step of the manufacture of the memory cell following FIG. 27;

FIG. 29 is a cross sectional view showing a main part of a split gate type MONOS memory cell according to a fourth embodiment of the present invention;

FIG. 30 is a cross sectional view showing the same main part as FIG. 29 in the step of the manufacture of the memory cell following FIG. 29;

FIG. 31 is a cross sectional view showing a main part of a split gate type MONOS memory cell in the step of manufacturing according to a fifth embodiment of the present invention;

FIG. 32 is a cross sectional view showing the same main part as FIG. 31 in the step of the manufacture of the memory cell following FIG. 31;

FIG. 33 is a cross sectional view showing the same main part as FIG. 31 in the step of the manufacture of the memory cell following FIG. 32;

FIG. 34 is a cross sectional view showing the same main part as FIG. 31 in the step of the manufacture of the memory cell following FIG. 33;

FIG. 35 is a cross sectional view showing a main part of a split gate type memory cell which the present inventors have examined; and

FIG. 36 is a cross sectional view showing a main part of a split gate type memory cell which the present inventors have examined.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Further, in the present embodiment, MIS•FET (Metal Insulator Semiconductor Field Effect Transistor) representing the field effect transistor is abbreviated as MIS, and an n-channel type MIS•FET is abbreviated as nMIS. In addition, an MOSFET (Metal Oxide Semiconductor FET) is a field effect transistor of a structure whose gate dielectric is made of a silicon oxide (SiO₂ and the like) film, and is considered to be included in the subordinate concept of the above MIS. In addition, it is needless to mention that an MONOS type memory cell mentioned in the present embodiment is also included in the subordinate concept of the above MIS. In addition, in the present embodiment, silicon nitride includes Si₃N₄ of course, but also includes a dielectric film of similar composition of silicon nitride. In addition, in the present embodiment, a wafer is mainly a Si (silicon) single crystal wafer, but also it includes an SOI (Silicon On Insulator) wafer, a dielectric film substrate on which integrated circuits are formed, and the like. Further, the form thereof includes not only a circle or a rough circle, but also a square, a rectangle, and the like.

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

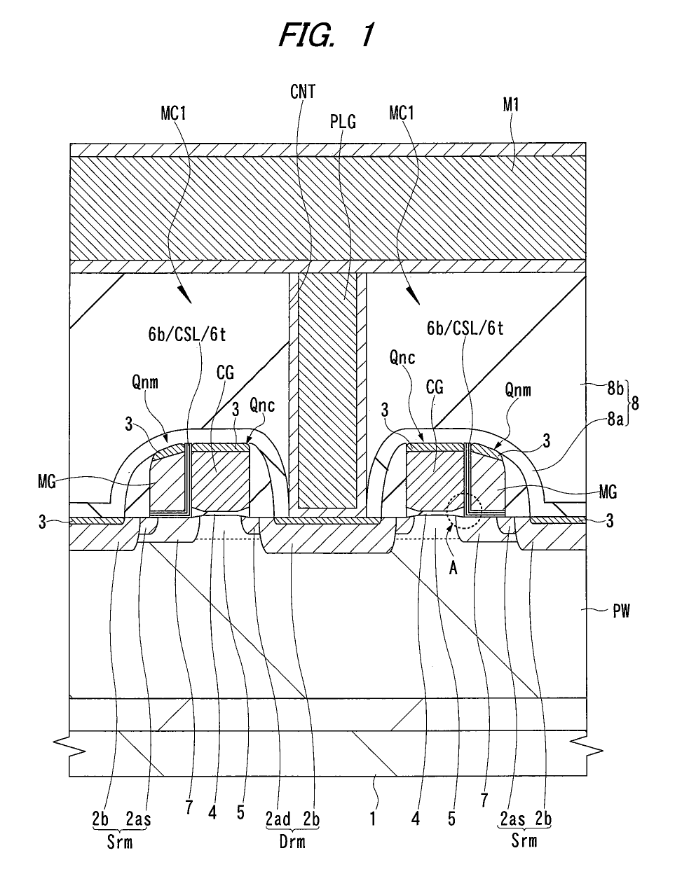

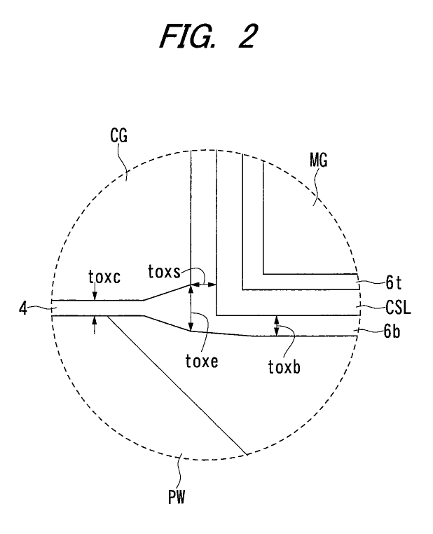

An example of the structure of a split gate type MONOS memory cell according to a first embodiment of the present invention will be explained with reference to FIGS. 1 and 2. FIG. 1 is a cross sectional view showing the main part of a split gate type MONOS memory cell in which the channel is cut along the direction intersecting to its memory gate electrode, and FIG. 2 is an enlarged cross sectional view of a main part showing the region A of FIG. 1.

As shown in FIG. 1, a semiconductor substrate 1 is made of, for example, p-type single crystal silicon, a p well PW into which p-type impurities are included is formed. In the active region of the main surface (device formation surface) of the semiconductor substrate 1, an nMIS (Qnc) for selection and an nMIS (Qnm) for memory of a memory cell MC1 according to the first embodiment are arranged. The drain region Drm and the source region Srm of this memory cell MC1 have, for example, n⁻-type semiconductor regions 2ad and 2as with relatively low density, and a n⁺-type semiconductor region 2b with relatively high density whose impurity concentration is higher than that of the n⁻-type semiconductor regions 2ad and 2as (LDD (Lightly Doped Drain) structure). The n⁻-type semiconductor regions 2ad and 2as are arranged in the channel region side of the memory cell MC1, and the n⁺-type semiconductor region 2b is arranged at the position apart by the n⁻-type semiconductor regions 2ad and 2as from the channel region side of the memory cell MC1.

On the main surface of the semiconductor substrate 1 between the drain region Drm and the source region Srm, the select gate electrode CG of the above nMIS (Qnc) for selection, and the memory gate electrode MG of the above nMIS (Qnm) for memory are extended adjacently, and a plurality of the memory cells MC1 are adjacent via an element isolation region formed on the semiconductor substrate 1 in the extending direction thereof. The select gate electrode CG is arranged in the first region of the main surface of the semiconductor substrate 1, and the memory gate electrode MG is arranged in the second region that is different from the first region in the main surface of the semiconductor substrate 1. The select gate electrode CG is made of, for example, an n-type polycrystalline silicon film, and the impurities concentration thereof is, for example, around 2×10²⁰cm⁻³, and the gate length thereof is, for example, around 100 to 150 nm. The memory gate electrode MG is made of, for example, an n-type polycrystalline silicon film, and the impurities concentration thereof is, for example, around 2×10²⁰cm⁻³, and the gate length thereof is, for example, around 50 to 100 nm.

On the upper surface of an n⁺-type semiconductor region 2b comprising a part of the select gate electrode CG, the memory gate electrode MG, the source region Srm and the drain region Drm, a silicide layer 3 made of, for example, cobalt silicide, nickel silicide, titanium silicide and the like is formed. In the MONOS type memory cell, it is necessary to supply electric potential to both of the select gate electrode CG and the memory gate electrode MG, and the movement speed thereof is dependent largely on the resistance value of the select gate electrode CG and the memory gate electrode MG. Therefore, it is preferable to attain the low resistance of the select gate electrode CG and the memory gate electrode MG by forming the silicide layer 3. The thickness of the silicide layer 3 is, for example, around 20 nm.

Between the select gate electrode CG and the main surface of the semiconductor substrate, a gate dielectric 4 made of a thin silicon oxide film of thickness, for example, around 1 to 5 nm is arranged. Therefore, the select gate electrode CG is arranged on the element isolation region and the first region of the semiconductor substrate 1 via the gate dielectric 4. Furthermore, the structure of the gate dielectric 4 is a bird's beak shape, and the thickness of the gate dielectric 4 under the gate longitudinal direction end is formed thicker than that of the gate dielectric 4 under the gate longitudinal direction center.

On the main surface of the semiconductor substrate 1 under the gate dielectric 4, for example, boron is introduced and a p-type semiconductor region 5 is formed. This semiconductor region 5 is the semiconductor region for the channel formation of the nMIS (Qnc) for selection, and the threshold voltage of the nMIS (Qnc) for selection is set to a specified value by this semiconductor region 5.

The memory gate electrode MG is arranged at one side of the side surfaces of the select gate electrode CG, and the insulation between the select gate electrode CG and the memory gate electrode MG is made by a dielectric film for charge retention in which a lower layer dielectric film 6b, a charge storage layer CSL and an upper layer dielectric film 6t are laminated (hereinafter, referred to as dielectric films 6b and 6t and charge storage layer CSL). In addition, on the second region of the semiconductor substrate 1 via the dielectric films 6b and 6t and the charge storage layer CSL, the memory gate electrode MG is arranged. Meanwhile, in FIG. 1, the notation of the dielectric films 6b and 6t and the charge storage layer CSL is expressed as 6b/CSL/6t.

The charge storage layer CSL is arranged in a state where the top and bottom thereof are pinched by the dielectric films 6b and 6t, and, for example, is made of a silicon nitride film and the thickness thereof is around 5 to 20 nm. The silicon nitride film is a dielectric film that has a discrete trap level in the film and has the function to accumulate a charge in this trap level. The dielectric films 6b and 6t are made of, for example, a silicon oxide film and the like, and the thickness of the lower layer dielectric film 6b is, for example, around 1.5 to 6 nm, and the thickness of the upper layer dielectric film 6t is, for example, around 0 to 8 nm. The dielectric films 6b and 6t may be made of a silicon oxide film including nitrogen.

On the main surface of semiconductor substrate 1, under the above lower layer dielectric film 6b, between the p-type semiconductor region 5 and the source region Srm, for example, arsenic or phosphor is introduced and an n-type semiconductor region 7 is formed. This semiconductor region 7 is a semiconductor region for the channel formation of the nMIS (Qnm) for memory, and the threshold voltage of the nMIS (Qnm) for memory is set to a specified value by this semiconductor region 7. Above the select gate electrode CG and the memory gate electrode MG, an interlayer dielectric 8 comprising a silicon nitride film 8a and a silicon oxide film 8b is formed, and a contact hole CNT reaching the drain region Drm is formed in this interlayer dielectric 8. To the drain region Drm, via a plug PLG buried in the contact hole CNT, a first metal layer M1 that extends in a second direction that is the direction intersecting to the memory gate electrode MG (or the select gate electrode CG) that extends in the first direction is connected. This wire M1 comprises a bit line of each memory cell MC1.

FIG. 2 shows an enlarged view of the gate dielectric 4, the lower layer dielectric film 6b, the charge storage layer CSL and the upper layer dielectric film 6t of the select gate electrode CG in the gap region of the memory cell MC1.

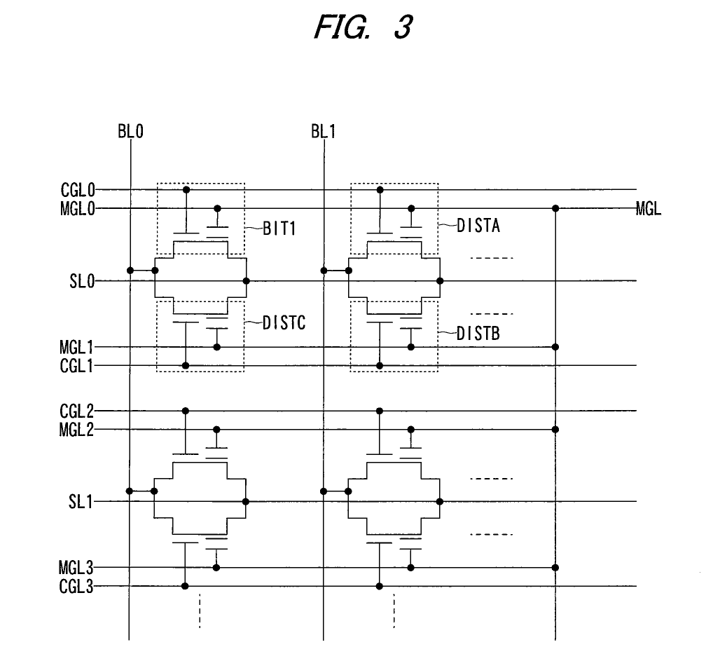

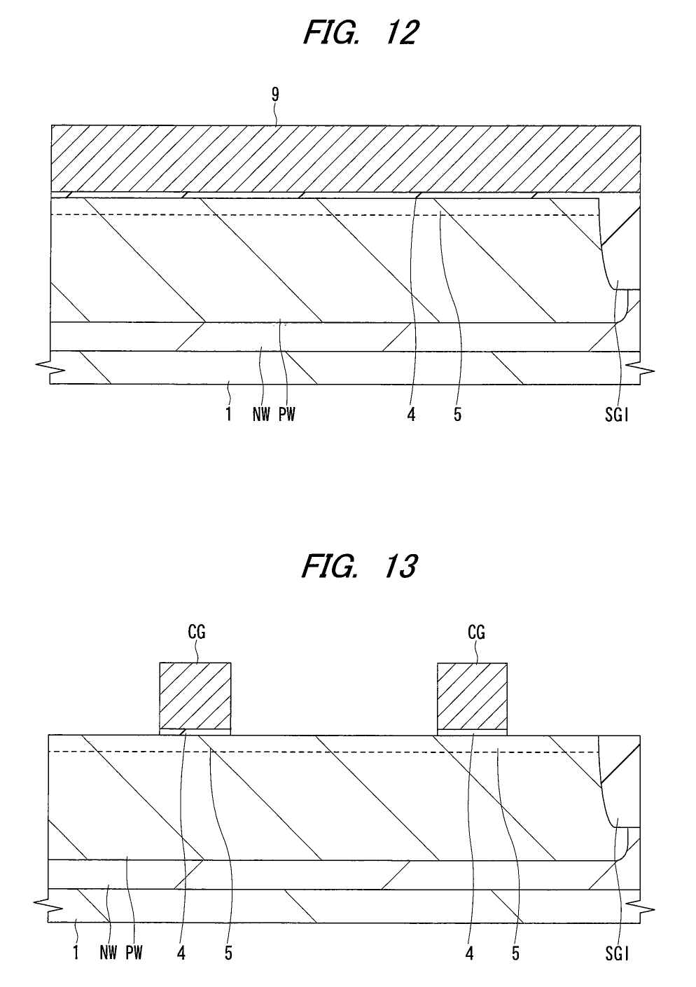

The characteristic of the memory cell MC1 explained in the first embodiment is that the structure of the gate dielectric 4 of the select gate electrode CG is the bird's beak shape, and in addition, the lower layer dielectric film 6b positioned between the select gate electrode CG and the charge storage layer CSL is not formed thick, but set to a specified thickness. In more concrete, (1) the thickness (toxe) of the gate dielectric 4 under the gate longitudinal direction end of the select gate electrode CG is formed thicker than that (toxc) of the gate dielectric 4 under the longitudinal direction center, and (2) the thickness of the lower layer dielectric film 6b which is positioned between the select gate electrode CG and the charge storage layer CSL and is nearest to the semiconductor substrate 1 (p well PW) (toxs) is 1.5 times or below of the thickness (toxb) of the lower layer dielectric film 6b positioned between the semiconductor substrate 1 and the charge storage layer CSL. Hereinafter, the array structure of this memory cell MC1 and the memory operations (program, program disturb, erase and read) will be explained in detail with reference to FIGS. 3 to 11, and the method of manufacturing this memory cell MC1 will be explained in detail with reference to FIGS. 12 to 20.

First, an example of the array structure of the split gate type MONOS memory cell according to the first embodiment of the present invention will be explained with reference to FIG. 3. FIG. 3 is a circuit diagram showing the array structure of the memory cell. In addition, in FIG. 3, only 2×4 memory cells are shown for simplification.

The select gate lines (word lines) CGL0 to CGL3 to connect the select gate electrode CG of each memory cell MC1, the memory gate lines MGL0 to MGL3 to connect the memory gate electrode MG, and the source lines SL0 and SL1 to connect the source region Srm that two adjacent memory cells share extend in the first direction respectively in parallel. Further, the bit lines BL0 and BL1 to connect the drain region Drm of the memory cell MC1 extend in the second direction, that is, in the direction intersecting perpendicularly to the select gate line CGL0 and the like. Meanwhile, these lines extend not only on the circuit diagram, but also on each memory cell MC1 or line layout in the above mentioned direction. In addition, the select gate line CGL0 and the like may comprise the select gate electrode CG, and may comprise the line to be connected to the select gate electrode CG.

To the source lines SL0 and SL1 and the memory gate lines MGL0 to MGL3, a high voltage is applied at the time of program/erase, therefore, a voltage up driver comprising a high withstand voltage MIS is connected (not shown). In addition, to the select gate lines CGL0 to CGL3, only a low voltage around 1.5V is applied, therefore, a voltage up driver with low withstand voltage and high speed is connected (not shown). 16, 32 or 64 memory cells are connected to one local bit line, and the local bit line is connected to a global bit line via the MIS to select local bit lines, and the global bit line is connected to a sense amplifier.

In the array structure shown in FIG. 3, the source lines SL0 and SL1 are wired every one wire independently, and a plurality of the memory gate lines MGL0 to MGL3 are connected and made as common memory gate line MGL, but a plurality of source lines SL0 and SL1 and a plurality of memory gate lines MGL0 to MGL3 may be connected and made each shared source line and memory gate line. By making them shared lines, the number of the drivers of the high withstand voltage to drive each line is decreased, and the chip area can be reduced. On the contrary, the source lines SL0 and SL1 and the memory gate lines MGL0 to MGL3 may be wired every one wire independently. In this case, the number of the drivers of the high withstand voltage increases, but it is possible to decrease the time subject to disturb at the time of program and erase.

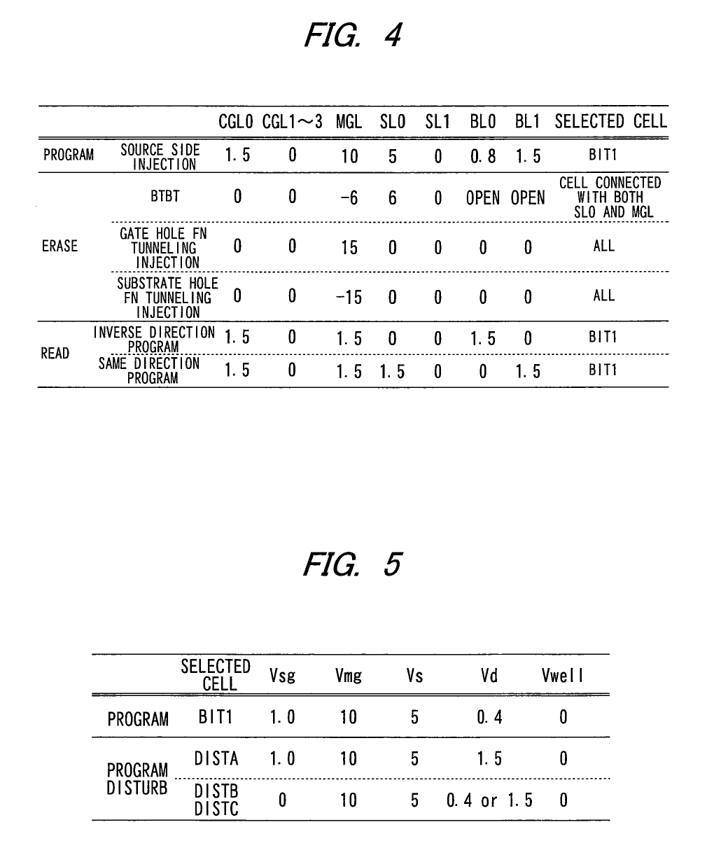

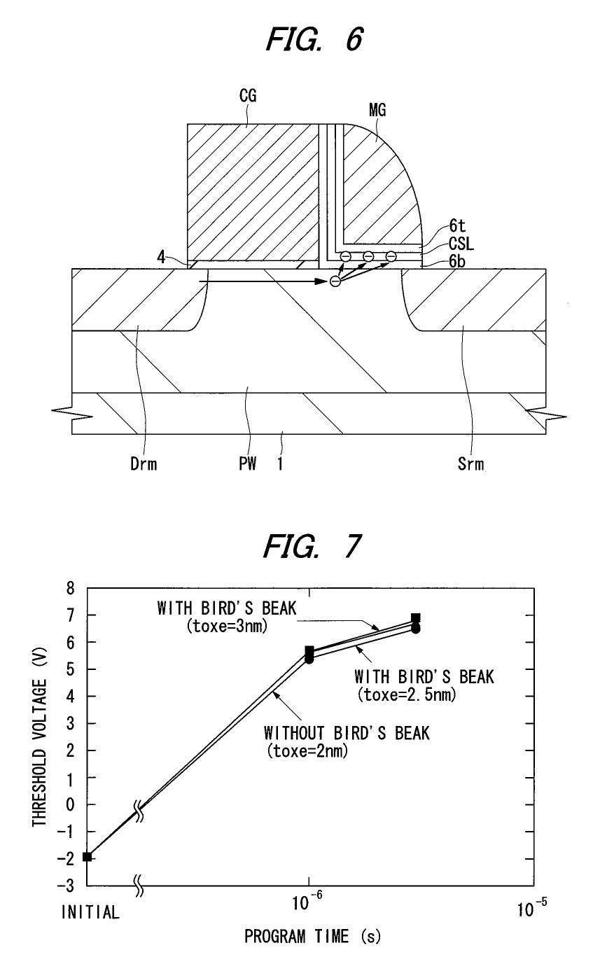

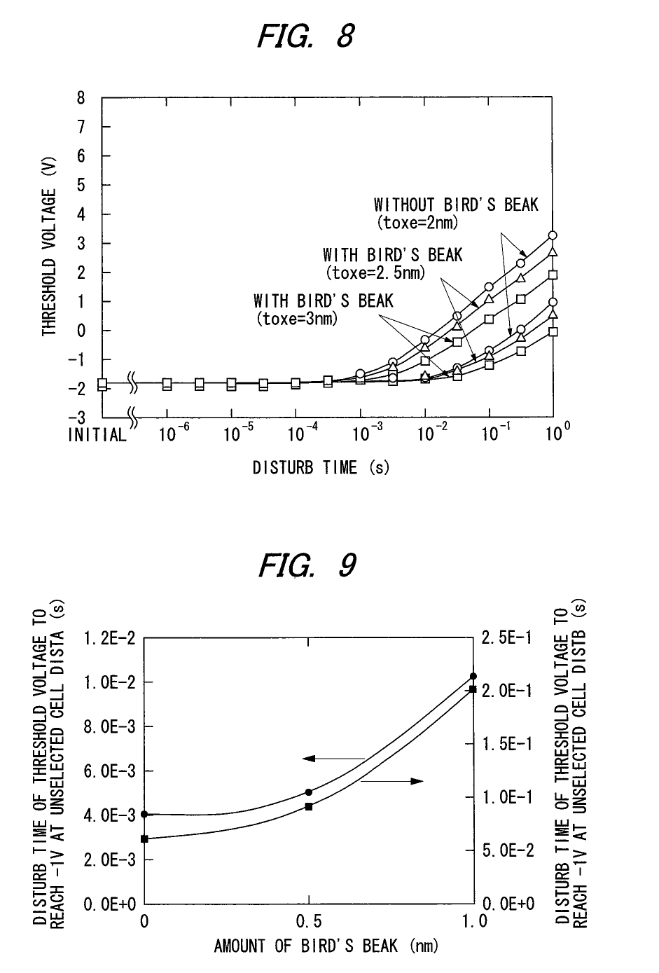

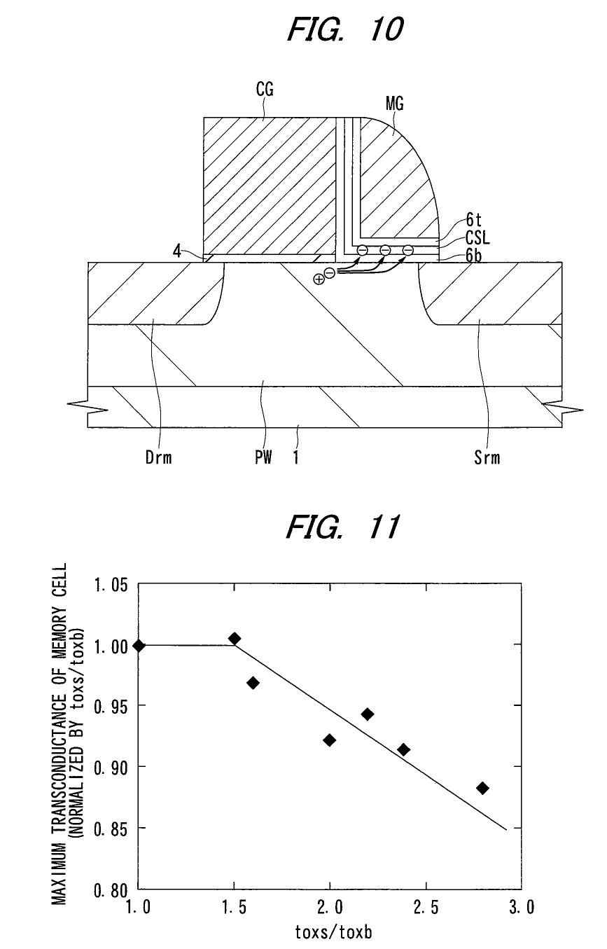

Next, an example of the memory operations (program, program disturb, erase and read) of the split gate type MONOS memory cell according to the first embodiment of the present invention will be explained with reference to FIGS. 4 to 11. FIG. 4 shows an example of the conditions of the voltage applied to the respective lines (the select gate lines CGL0 to CGL3, the memory gate line MGL, the source lines SL0 and SL1, the bit lines BL0 and BL1) at the time of program, erase, and read of the select cell BIT1 shown in the above FIG. 3, FIG. 5 shows an example of the conditions of the voltage applied to the respective terminals of the select cell BIT1, unselected cells DISTA, DISTB and DISTC, in the case to write information to select cell BIT1 shown in the above FIG. 3, FIG. 6 is a cross sectional view of a main part of the memory cell to explain the actions of charge of program select memory cell, FIG. 7 is a graph showing the program characteristics of the memory cell, FIG. 8 is a graph showing the disturb characteristics, FIG. 9 is a graph showing the relation between the quantity of bird's beak of the gate dielectric under the gate longitudinal direction end of the select gate electrode and the disturb time at which the threshold voltage reaches −1V, FIG. 10 is a cross sectional view of the main part of the memory cell for explaining the mechanism of the electron injection at the time of the disturb, and FIG. 11 is a graph showing the relation between the thickness of the lower layer dielectric film positioned between the select gate electrode and the charge storage layer and the maximum transconductance of the nMIS for memory. Herein, the injection of electrons to the charge storage layer CSL is defined as “program”, and the injection of holes is defined as “erase”.

The “program” and the “program disturb” will be explained.

The program is performed by so-called SSI method. The unselected cell DISTA is a memory cell connected to the memory gate line MGL, the source line SL0 and the select gate line CGL1 as with the select cell BIT1, and the unselected cells DISTB and DISTC are memory cells connected to the memory gate line MGL and the source line SL0 as with the select cell BIT1.

As shown in FIGS. 4 and 5, the voltage Vs to be applied to the source region Srm of the select cell BIT1 is set 5V, the voltage Vmg to be applied to the memory gate electrode MG is set 10V, and the voltage Vsg to be applied to the select gate electrode CG is set 1V. The voltage Vd to be applied to the drain region Drm is so controlled that the channel current at the time of the program becomes a certain set value. The voltage Vd at this moment is decided by the threshold voltage of the set value of the channel current and the threshold value of the MIS (Qnc) for select, and for example, it is around 0.4V at the set current value 1 μA. The voltage Vwell to be applied to the p well PW is 0V.

FIG. 6 shows the movement of the charge when the program voltage is applied to the select cell BIT1. A voltage larger than that of the drain region Drm is applied to the select gate electrode CG and the MIS (Qnc) for select is turned on, and a positive high voltage is applied to the source region Srm, and then electrons flow from the drain region Drm to the source region Srm. The electrons flowing through the channel region are accelerated in the channel region under and near the boundary between the select gate electrode CG and the memory gate electrode MG (between the source region Srm and the drain region Drm) and become hot electrons. The hot electrons are drawn to the memory gate electrode MG by the positive voltage applied to the memory gate electrode MG and are injected into the charge storage layer CSL under the memory gate electrode MG. The injected hot electrons are captured by traps in the charge storage layer CSL, and as a result, the electrons are accumulated in the charge storage layer CSL, and the threshold voltage of the nMIS (Qnm) for memory rises.

In the unselected cell DISTA that receives the program disturb, the voltage Vs to be applied to the source region Srm is set 5V, the voltage Vmg to be applied to the memory gate electrode MG is set 10V, the voltage Vsg to be applied to the select gate electrode CG is set 10V, and the same voltage as that of the select cell BIT11 is applied. The voltage Vd to be applied to the drain region Drm is different from select cell BIT1, and it is set 1.5V that is larger than the voltage Vsg to be applied to the select gate electrode CG. By impressing the voltage larger than that of the select gate electrode CG to the drain region Drm, and turning off the nMIS (Qnc) for select, the program is prohibited.

In the unselected cells DISTB and DISTC that receive the program disturb, the voltage Vs to be applied to the source region Srm is set 5V, the voltage Vmg to be applied to the memory gate electrode MG is set 10V, and the same voltage as that of the select cell BIT1 is applied. The voltage Vsg to be applied to the select gate electrode CG is set unselected 0V, and the voltage Vd to be applied to the drain region Drm is set 0.4V in the case of the unselected cell connected to the bit line BL0 same as the select cell BIT1, and is set 1.5V in the case of the unselected cell connected to the bit line BL1 different from the select cell BIT1. By impressing the voltage Vd larger than the voltage Vsg to be applied to the select gate electrode CG to the drain region Drm, and turning off the nMIS (Qnc) for select, the program is prohibited.

In FIGS. 7 and 8, the program characteristic and the disturb characteristic of the memory cell according to the first embodiment are shown. For comparison, the program characteristic and the disturb characteristic of the memory cell (hereinafter, referred to simply as conventional memory cell) without the bird's beak in the gate dielectric 4 of the nMIS (Qnc) for select are also shown in these figures. In FIGS. 7 and 8, the respective characteristics of the memory cell A according to the first embodiment in which there is the bird's beak in the gate dielectric 4 of the nMIS (Qnc) for select, and the thickness (toxc) of the gate dielectric 4 under the gate longitudinal direction center of the select gate electrode CG is 2 nm, the thickness (toxe) of the gate dielectric 4 under the gate longitudinal direction end of the select gate electrode CG is 2.5 nm, the memory cell B according to the first embodiment in which there is the bird's beak in the gate dielectric 4 of the nMIS (Qnc) for select, and the thickness (toxc) of the gate dielectric 4 under the gate longitudinal direction center of the select gate electrode CG is 2 nm, the thickness (toxe) of the gate dielectric 4 under the gate longitudinal direction end of the select gate electrode CG is 3 nm, and the conventional memory cell C in which there is not the bird's beak in the gate dielectric 4 of the nMIS for select, and the thickness of the gate dielectric is 2 nm.

As shown in FIG. 7, in the memory cells A and B according to the first embodiment and the conventional memory cell C, the program speeds are hardly different. That is, the program speed does not depend upon the thickness of the gate dielectric 4 of the select gate electrode CG. As for this, it is considered that electrons to be injected by the program are supplied from the drain region Drm, and this electron supply quantity is not affected by the bird's beak of the select gate electrode CG.

In contrast, as shown in FIG. 8, with regard to the disturb characteristic, in both of the unselected cell DISTA in which the voltage Vsg to be applied to the select gate electrode CG is 1V and the unselected cells DISTB and DISTC in which the voltage Vsg to be applied to the select gate electrode CG is 0V, as the thickness of the gate dielectric 4 under the gate longitudinal direction end of the select gate electrode CG (toxe) increases, the rise of the threshold voltage is restrained. That is, the disturb tolerance is improved by introducing the bird's beak under the gate longitudinal end of the select gate electrode CG.

FIG. 9 shows the relation between the quantity of the bird's beak of the gate dielectric 4 under the gate longitudinal direction end of the select gate electrode CG and the disturb time at which the threshold voltage reaches −1V. The difference between the thickness (toxc) of gate dielectric 4 under the gate longitudinal direction center of the select gate electrode CG and the thickness (toxe) of gate dielectric 4 under the gate longitudinal direction end of the select gate electrode CG is made the quantity of the bird's beak.

As shown in FIG. 9, when the quantity of the bird's beak becomes larger, the time until the threshold voltage rises 1V becomes longer, and it is understood that the disturb tolerance is improved. When the quantity of the bird's beak becomes 0.5 nm or more, the disturb tolerance is improved rapidly.

FIG. 10 shows the mechanism of the electron injection at the time of disturb. When the disturb voltage of the above FIG. 5 is applied, the positive voltage is applied to the memory gate electrode MG, and a channel region is formed under the memory gate electrode MG. Therefore, the high voltage of 5V applied to the source region Srm reaches the neighborhood of the end of the select gate electrode CG. Since a voltage bigger than voltage Vsg to be applied to the select gate electrode CG (1V or 0V) is applied further under the gate dielectric 4 under the gate longitudinal direction end of the select gate electrode CG, so-called GIDL (Gate Induced Drain Leakage) current flows. This GIDL current is generated by an electron-hole pair generated in the semiconductor substrate 1 (semiconductor region 5) under the gate longitudinal direction end of the select gate electrode CG, and electrons are pulled to the positive high voltage applied to the source region Srm and the memory gate electrode MG and injected into the charge storage layer CSL. In the disturb characteristic shown in the above FIG. 8, the rise of the threshold voltage becomes larger in the unselected cells DISTB and DISTC in which the voltage Vsg applied to the select gate electrode CG is 0V than the unselected cell DISTA in which the voltage Vsg applied to the select gate electrode CG is 1V, and it is thought that the electron injection of the disturb is caused by not the channel current between the drain region Drm and the source region Srm, but the GIDL current under the select gate electrode CG. When the bird's beak is introduced, the vertical direction electric field working on the gate dielectric 4 on the point where the electron-hole pair is generated becomes small, and as a result, the GIDL current decreases, and the disturb tolerance is improved.

Next, the “erase” will be explained.

As shown in the “erase” column of the above FIG. 4, the erase is performed by either BTBT erase in which holes are generated by a BTBT (Band-To-Band Tunneling) phenomenon and hot holes are injected into the charge storage layer CSL, or an FN erase in which holes are injected into the charge storage layer from the memory gate electrode MG or the semiconductor substrate 1 by an FN (Fowler-Nordheim) tunneling.

When the BTBT erase is performed, the voltage Vmg to be applied to the memory gate electrode MG is set −6V, the voltage Vs to be applied to the source region Srm is set 6V, the voltage Vsg to be applied to the select gate electrode CG is set 0V, and the drain region Drm is made into a floating state. 0V is applied to the p well PW (Vwell). When the above voltage is applied, holes generated by the BTBT phenomenon at the end of the source region Srm by the voltage working between the source region Srm and the memory gate electrode MG are accelerated by the high voltage applied to the source region Srm and become hot holes, and the hot holes are pulled to the direction of the memory gate electrode MG by the high voltage applied to the memory gate electrode MG, and are injected into the charge storage layer CSL. The injected hot holes are captured by traps in the charge storage layer CSL, and the threshold voltage of the nMIS (Qnm) for memory decreases.

In the case of the FN erase where holes are injected from the memory gate electrode MG, in order for the FN tunnel injection of holes to be easily caused, the thickness of the upper layer dielectric film 6t in the memory cell MC1 of the above FIG. 1 is set 3 nm or less, or the upper dielectric film 6t is omitted. In the case of the structure where there is the upper layer dielectric film 6t, for holes to be easily injected, it is preferable that a silicon nitride film or an amorphous silicon film of the thickness around 1 nm is inserted between the upper layer dielectric film 6t. In addition, in the case of the structure without the upper layer dielectric film 6t, for holes to be injected more easily, it is preferable that the charge storage layer CSL is made into the structure where an silicon oxynitride film is used, or the structure where a silicon nitride film and an silicon oxynitride film are laminated from the semiconductor substrate side sequentially. With regard to the applied voltage of the FN erase to inject holes from the memory gate electrode MG to the charge storage layer CSL, the voltage Vmg to be applied to the memory gate electrode MG is set 15V, and the voltage Vs to be applied to the other source region Srm, the voltage Vsg to be applied to the select gate electrode CG, the voltage Vd to be applied to the drain region Drm, and the voltage Vwell to be applied to the p well PW are set 0V. When the above voltage is applied, holes are injected from the memory gate electrode MG into the charge storage layer CSL by the FN tunneling. In addition, electrons accumulated in the charge storage layer CSL at the time of program are pulled up to the memory gate electrode MG.

In the case of the FN erase to inject holes from the semiconductor substrate 1, in order for the FN tunnel injection of holes to be easily caused, the thickness of the lower layer dielectric film 6b in the memory cell MC1 shown in the above FIG. 1 is set 3 nm or less, or for holes to be injected more easily, a silicon nitride film or an amorphous silicon film of the thickness around 1 nm is inserted between the lower layer dielectric film 6b. With regard to the applied voltage of the FN erase to inject holes from the semiconductor substrate 1 into the charge storage layer CSL, the voltage Vmg to be applied to the memory gate electrode MG is set −15V, and the voltage Vs to be applied to the other source region Srm, the voltage Vsg to be applied to the select gate electrode CG, the voltage Vd to be applied to the drain region Drm, and the voltage Vwell to be applied to the p well PW are set 0V. When the above voltage is applied, holes are injected from the semiconductor substrate 1 into the charge storage layer CSL by tunneling. In addition, electrons accumulated in the charge storage layer CSL at the time of program are pulled up to the semiconductor substrate 1.

Next, the “read” will be explained.

As shown in the “read” column of the above FIG. 4, for read, there are two kinds of the methods, that is, a method to read by flowing a current in the opposite direction to program, and a method to read by flowing a current in the same direction. As shown in the above FIG. 4, in the case to read by flowing a current in the opposite direction to program, the voltage Vd to be applied to the drain region Drm is set 1.5V, the voltage Vs to be applied to the source region Srm is set 0V, the voltage Vsg to be applied to the select gate electrode CG is set 1.5V, and the voltage Vmg to be applied to the memory gate electrode MG is set 1.5V. In the case to read by flowing a current in the same direction, voltage Vd to be applied to the drain region Drm and the voltage Vs to be applied to the source region Srm are replaced, and they are set 0V and 1.5V, respectively.

The voltage Vmg to be applied to the memory gate electrode MG at the time of the read is set between the threshold voltage of the nMIS (Qnm) for memory in the program state and the threshold voltage of the nMIS (Qmn) for memory in the erase state. When the threshold voltages in the program state and in the erase state are set 4V and −1V, respectively, the voltage Vmg at the time of the above read is the intermediate value of the both. By making it the intermediate value, even if the threshold voltage of the program state falls 2V during data retention, and even if the threshold voltage of the erase state rises 2V, it is possible to distinguish the program state and the erase state, and the margin of the data retention characteristic is made wide. If the threshold voltage of the memory cell MC1 in the erase state is lowered enough, the voltage Vmg at the time of the read can be made 0V. By making the voltage Vmg at the time of the read 0V, it is possible to avoid the read disturb, that is, the fluctuation of the threshold voltage by the voltage applied to the memory gate electrode MG.

In the memory cell MC1 according to the first embodiment, in the oxidation process to introduce the bird's beak into the gate dielectric 4 of the select gate electrode CG, a thick dielectric film is formed on the side of the select gate electrode CG, and if this thick dielectric film is left when the memory cell MC is finished, the read current decreases.

FIG. 11 shows the relation between the thickness (toxs) of the lower layer dielectric film 6b which is positioned between the select gate electrode CG and the charge storage layer CSL and is nearest to the semiconductor substrate 1 and the maximum transconductance of the nMIS (Qmn) for memory. The thickness (toxs) of the lower layer dielectric film 6b which is positioned between the select gate electrode CG and the charge storage layer CSL and is nearest to the semiconductor substrate is expressed by the ratio to the thickness of the lower layer dielectric film 6b which is positioned between the semiconductor substrate 1 and the charge storage layer CSL (toxb). With regard to the maximum transconductance of the nMIS (Qnm) for memory, the larger the value thereof is, the larger read current can be obtained, and it is standardized by the value when the ratio toxs/toxb of the thickness (toxs) of the lower layer dielectric film 6b which is positioned between the select gate electrode CG and the charge storage layer CSL, and is nearest to the semiconductor substrate 1 to the thickness (toxb) of the lower layer dielectric film 6b which is positioned between the semiconductor substrate 1 and the charge storage layer CSL is 1.

As shown in FIG. 11, when ratio toxs/toxb of the thickness (toxs) of the lower layer dielectric film 6b which is positioned between the select gate electrode CG and the charge storage layer CSL and is nearest to the semiconductor substrate 1 to the thickness (toxb) of the lower layer dielectric film 6b which is positioned between the semiconductor substrate 1 and the charge storage layer CSL is 1.5 times or less, a large transconductance can be secured, and a large read current can be provided. However, when the above ratio toxs/toxb becomes more than 1.5 times, the transconductance becomes small, and the read current decreases. When the distance between the select gate electrode CG and the memory gate electrode MG is made large, the region that is hard to be affected by the voltage of the select gate electrode CG and the memory gate electrode MG appears in the channel regions under both of the electrodes, and it expands and the resistance components of the channel region under both the electrodes increases. Therefore, the read current decreases.

The voltage conditions of the memory operation are shown in the above FIGS. 4 and 5, but these conditions are one example, and the present invention is not limited to these numerical values mentioned above.

Next, an example of the method of manufacturing the split gate type MONOS memory cell according to the first embodiment of the present invention will be explained with reference to FIGS. 12 to 21. FIGS. 12 to 16 and FIGS. 18 to 21 show cross sectional views showing the main part of the memory cell in the step of the manufacture of the semiconductor device, and shows the same main part as that in the cross sectional view of the memory cell shown in the above FIG. 1, and FIG. 17 is a graph showing the relation between the oxidation speed and the temperature of polycrystalline silicon and single crystal silicon.

First, as shown in FIG. 12, a semiconductor substrate comprising p-type single crystal silicon having the specific resistance of, for example, 1 to 10Ω·cm (a sheet of the semiconductor in roughly circular plane shape referred to as a semiconductor wafer at this stage) 1 is prepared. Then, on the main surface of the semiconductor substrate 1, for example, a trench-shaped element isolation region SGI and an active region arranged so as to be surrounded by this are formed. That is, after an isolation trench is formed in a specified point of the semiconductor substrate 1, on the main surface of the semiconductor substrate 1, a dielectric film comprising, for example, a silicon oxide film is accumulated, and further, the dielectric film is polished by the CMP (Chemical Mechanical Polishing) method and the like so that the dielectric film is left only in the isolation trench, and thereby, an element isolation region SGI is formed.

Next, a predetermined or specified impurity is guided into the specified part of the semiconductor substrate 1 selectively with specified energy by the ion implantation method and the like, and thereby, an embedded n well NW and p well PW are formed. Then, a p-type impurity, for example, boron is ion implanted into the main surface of semiconductor substrate 1, and thereby, a p-type semiconductor region 5 for channel formation of the nMIS (Qnc) for select is formed. The ion implantation energy of this p-type impurity is, for example, around 20 keV, and the dose quantity thereof is, for example, around 1.5×10¹³cm⁻².

Next, by performing oxidation processing to the semiconductor substrate 1, on the main surface of the semiconductor substrate 1, a gate dielectric 4 of thickness, for example 1 to 5 nm comprising a silicon oxide film is formed. Then, on the main surface of the semiconductor substrate 1, a first conductive film 9 comprising a polycrystalline silicon film having an impurity concentration of, for example, 2×10²⁰cm⁻³ is accumulated. This first conductive film 9 is formed by the CVD (Chemical Vapor Deposition) method, and, the thickness thereof is, for example, around 150 to 250 nm.

Next, as shown in FIG. 13, the above first conductive film 9 is processed with a resist pattern as a mask, and thereby a select gate electrode CG is formed. The gate length of the select gate electrode CG is, for example, 100 to 150 nm. The select gate electrode CG extends in the depth direction of the drawing, and is a linear pattern. For example, this pattern is equivalent to the select gate lines CGL0 to CGL3 in the array structure of the memory cell shown in the above FIG. 3. Then, the exposed gate dielectric 4 is removed by, for example, hydrofluoric acid water solution.

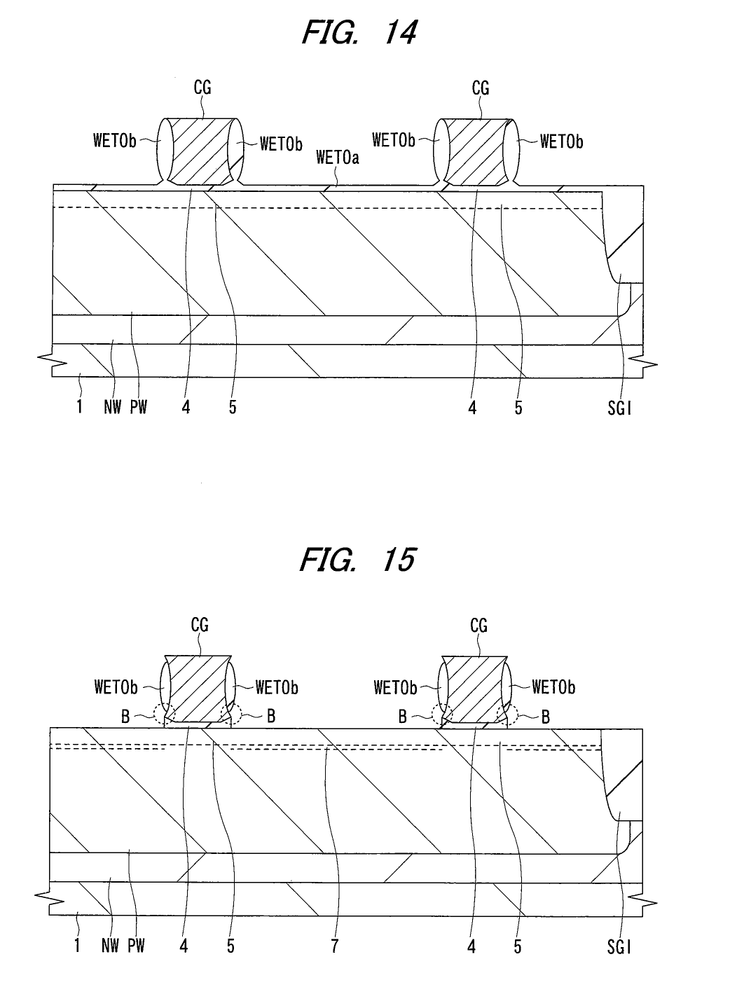

Next, as shown in FIG. 14, by performing wet oxidation processing to the semiconductor substrate 1, a silicon oxide film WETOa of the thickness of, for example, around 4 nm is formed on the main surface of the semiconductor substrate 1. The temperature of the wet oxidation processing is, for example, 750° C. When the wet oxidation processing is carried out, the polycrystalline silicon film at the side of the select gate electrode CG is oxidized at increased or accelerated speed, and a bell-shaped silicon oxide film WETOb is formed at the side of the select gate electrode CG. When the wet oxidation processing is further performed, a bird's beak is formed on the gate dielectric 4 under the gate longitudinal direction end between the select gate electrode CG and the semiconductor substrate 1 (semiconductor region 5). By the above conditions of the wet oxidation processing, the thickness (toxe) of the gate dielectric 4 under the gate longitudinal direction end of the select gate electrode CG can be made thicker around 1 nm than that (toxc) of the gate dielectric 4 under the gate longitudinal direction center. In a substitution of the wet oxidation processing, the dry oxidation processing may be used. As for the dry oxidation processing, the bird's beak is unlikely to be formed in comparison with the wet oxidation processing, therefore, the quantity of oxide is increased than that in the wet oxidation processing. For example, the dry oxidation processing is performed until the silicon oxide film WETOa of the thickness of around 6 nm is formed on the main surface of semiconductor substrate 1. The temperature of the dry oxidation processing is, for example, 800° C. In the case of dry oxidation processing, the polycrystalline silicon film at the side surface of the select gate electrode CG is oxidized at about the same speed in the side surface.

Next, as shown in FIG. 15, by the wet etching method using, for example, hydrofluoric acid water solution, the silicon oxide films WETOa and WETOb are etched while a part of the silicon oxide film WETOb is left. At this moment, the thickness of the silicon oxide film WETOb left in the lower part of the side surface of the select gate electrode CG shown by the region B in the figure is controlled so as to be below or less than that of the lower layer dielectric film 6b of a dielectric film for charge holding formed later. The silicon oxide film WETOb may be etched until the lower part of the side surface of the select gate electrode CG is exposed. By the above etching, the silicon oxide film WETOb is left in the central part of the side surface of the select gate electrode CG, but this does not have an influence on the electric characteristic of memory cell MC1. Then, with the select gate electrode CG and the resist pattern as a mask, an n-type impurity, for example, arsenic or phosphor is ion-implanted onto the main surface of the semiconductor substrate 1 so as to form an n-type semiconductor region 7 for the channel formation of the nMIS for memory. The ion implantation energy of this n-type impurity is, for example, around 25 keV, and the dose quantity thereof is, for example, around 6.5×10¹²cm⁻².

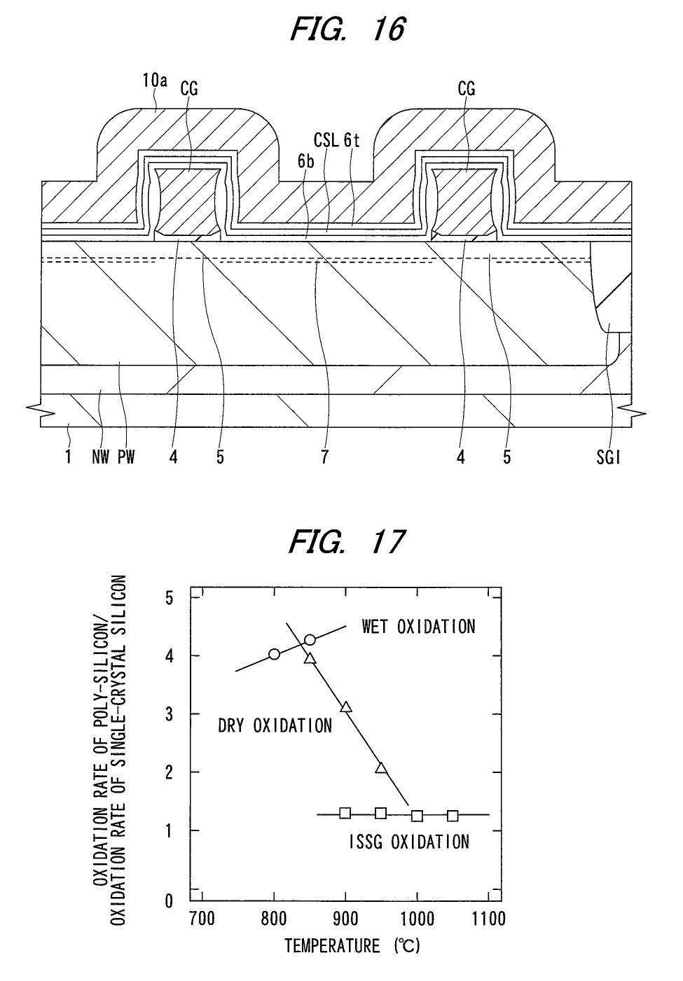

Next, as shown in FIG. 16, on the main surface of the semiconductor substrate 1, a lower layer dielectric film 6b comprising, for example, a silicon oxide film, a charge storage layer CSL comprising a silicon nitride film and an upper layer dielectric film 6t comprising a silicon oxide film are accumulated sequentially. The lower layer dielectric film 6b is formed by the ISSG (In-Situ Stream Generation) oxidation method, and the thickness thereof is, for example, around 1.5 to 6 nm, the charge storage layer CSL is formed by the CVD method, and the thickness thereof is, for example, around 5 to 20 nm, and the upper layer dielectric film 6t is formed by the ISSG oxidation method or the CVD method, and the thickness thereof is, for example, around 0 to 8 nm.

The reason why the ISSG oxidation method is used for the film formation of the lower layer dielectric film 6b is because the single crystal silicon comprising the semiconductor substrate 1 and the polycrystalline silicon film comprising the select gate electrode CG are oxidized at about the same speed, even not at a high temperature. FIG. 17 shows the ratio of the oxidation speed of the polycrystalline silicon and the oxidation speed of the single crystal silicon by use of the wet oxidation method, the dry oxidation method and the ISSG oxidation method. When the oxidation temperature is 900° C., by use of the wet oxidation method and the dry oxidation method, the polycrystalline silicon is oxidized at the speed that is 3 times or more of the single crystal silicon, but by use of the ISSG oxidation method, the polycrystalline silicon and the single crystal silicon can be oxidized at about the same speed.

Therefore, because it is possible to make the thickness (toxs) of the lower layer dielectric film 6b which is positioned at the side surface of the select gate electrode CG, and is nearest to the semiconductor substrate 1 roughly same as that (toxb) of the lower layer dielectric film 6b on semiconductor substrate 1, as explained with reference to the above FIG. 11, it is possible not to reduce the read current of memory cell MC. Further, in the ISSG oxidation method, in the silicon on whose surface the oxide film is already formed, it is advantageous in that the oxidation is hard to advance because the active oxidation radical which is the oxidizing species is hard to reach the surface of the silicon. Thereby, even if the silicon oxide film WETOb remains in the lower part of the side surface of the select gate electrode CG shown by the b region in the above FIG. 15 at the same thickness as that of the lower layer dielectric film 6b, the thickness of the silicon oxide film WETOb does not increase largely during the ISSG oxidation, and it is possible to restrain the decrease of the read current. When the oxidation temperature is raised to the neighborhood of 1000° C., it is possible to form the lower layer dielectric film 6b without forming a thick oxide film on the side surface of the select gate electrode CG even in the dry oxidation method. Because the oxidation temperature is high, the diffusion of impurities happens, but the batch-type oxidation device can be used, therefore, it is possible to realize a high throughput in the oxidation process.

The structures of respective films comprising the dielectric films 6b and 6t and the charge storage layer CSL differ with the usage of the semiconductor device to be manufactured, therefore, only representative structures and values are described herein, but the present invention is not limited to the above structures and values.

Next, on the main surface of the semiconductor substrate 1, a second conductive film 10a comprising a polycrystalline silicon film having the impurity concentration of, for example, 2×10²⁰cm⁻³ is accumulated. This second conductive film 10a is formed by the CVD method, and, the thickness thereof is, for example, around 50 to 100 nm.

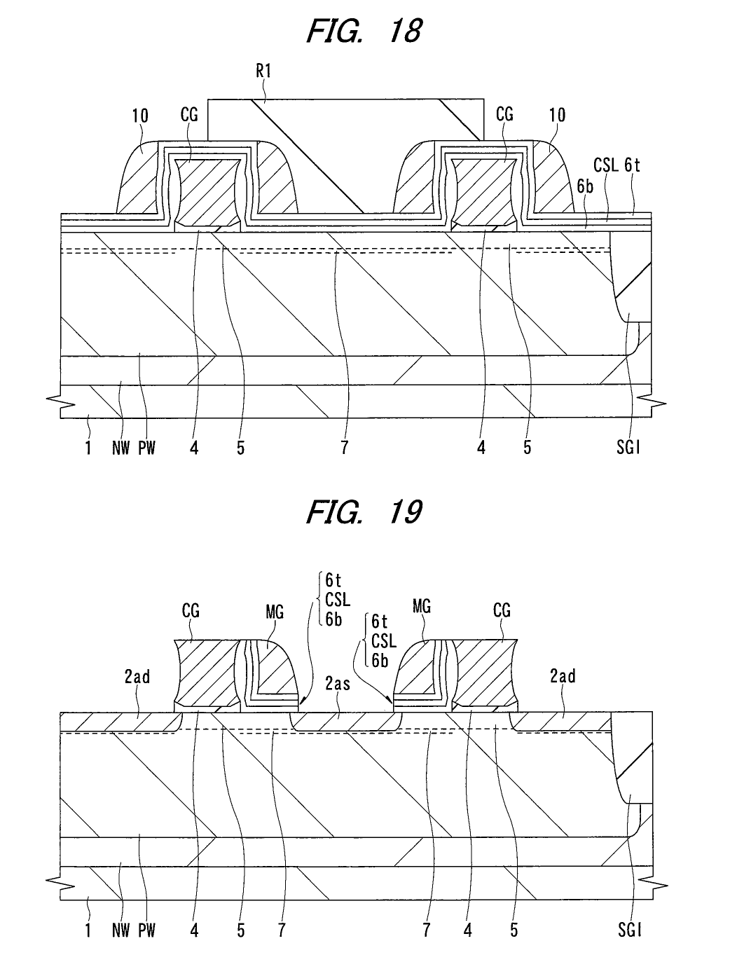

Next, as shown in FIG. 18, the above second conductive film 10a is etched back by anisotropic dry etching method, and thereby a sidewall 10 is formed via the dielectric films 6b and 6t and the charge storage layer CSL on both sides of the select gate electrode CG. Although its illustration is omitted, a second conductive film 10a is processed with the resist pattern as a mask, a draw part is formed in the region to form a contact hole to connect to the memory gate electrode MG later. Further, in the formation process of this sidewall 10, the second conductive film 10a is etched back with the upper layer dielectric film 6t as an etching stopper layer, but it is preferable to set the etching conditions of low damage so that the upper layer dielectric film 6t and the charge storage layer CSL under the same do not suffer damage by the etch back. When the upper layer dielectric film 6t and the charge storage layer CSL are damaged, the characteristic deterioration of the memory cell such as deterioration of the charge holding characteristics will occur.

Next, with a resist pattern R1 as a mask, the sidewall 10 exposing therefrom is etched, and a memory gate electrode MG comprising the sidewall 10 is formed in only the one side of the side surfaces of the select gate electrode CG. The gate length of the memory gate electrode MG is, for example, around 50 to 100 nm.

Next, as shown in FIG. 19, after the resist pattern R1 is removed, the dielectric films 6b and 6t and the charge storage layer CSL in other regions are etched selectively than the dielectric films 6b and 6t and the charge storage layer CSL between the select gate electrode CG and the memory gate electrode MG and between the semiconductor substrate 1 and the memory gate electrode MG.

Next, after a resist pattern whose end is positioned on the top surface of the select gate electrode CG and that covers a part of the select gate electrode CG on the opposite side to the memory gate electrode MG is formed, with the select gate electrode CG, the memory gate electrode MG and the resist pattern as a mask, an n-type impurity, for example, arsenic is ion implanted to the main surface of the semiconductor substrate 1, and on the main surface of the semiconductor substrate 1, an n⁻-type semiconductor region 2as is formed in a self-aligning manner to the memory gate electrode MG. At this time, the ion implantation energy of this n⁻-type impurity is, for example, around 5 keV, and the dose quantity thereof is, for example, around 1×10¹⁵cm⁻².

Next, after a resist pattern whose end is positioned in the top surface of the select gate electrode CG and that covers a part of the select gate electrode CG on the side to the memory gate electrode MG and the memory gate electrode MG is formed, with the select gate electrode CG, the memory gate electrode MG and the resist pattern as a mask, an n-type impurity, for example, arsenic is ion implanted to the main surface of the semiconductor substrate 1, and on the main surface of the semiconductor substrate 1, an n⁻-type semiconductor region 2ad is formed in a self-aligning manner to the select gate electrode CG. The ion implantation energy of this n-type impurity is, for example, around 7 keV, and the dose quantity thereof is, for example, around 1×10¹⁵cm⁻².

Herein, the n⁻-type semiconductor region 2as is formed first, and then the n⁻-type semiconductor region 2ad is formed, but the n⁻-type semiconductor region 2ad may be formed first, and then the n⁻-type semiconductor region 2as may be formed, or the n⁻-type semiconductor regions 2as and 2ad may be formed at the same time. Further, after the ion implantation of the n-type impurity to form the n⁻-type semiconductor region 2ad, a p-type impurity, for example, boron may be ion implanted into the main surface of the semiconductor substrate 1, and a p-type semiconductor region may be formed so as to surround the lower part of the n⁻-type semiconductor regions 2as and 2ad. The ion implantation energy of this p-type impurity is, for example, around 20 keV, and the dose quantity thereof is, for example, around 2.5×10¹³cm⁻².

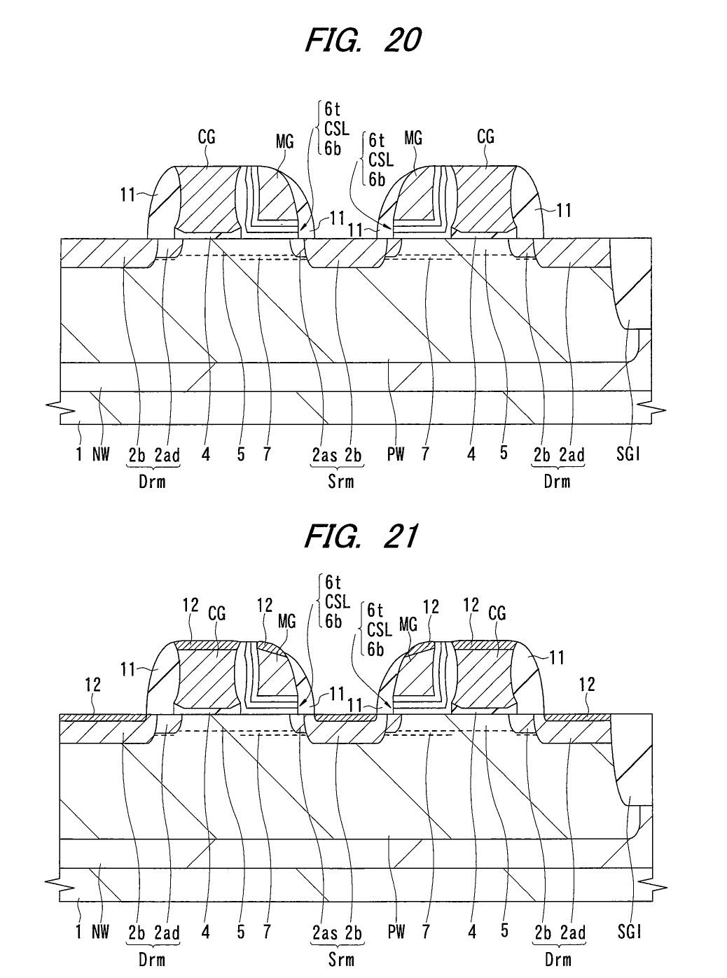

Next, as shown in FIG. 20, on the main surface of the semiconductor substrate 1, a dielectric film of thickness around 80 nm comprising, for example, a silicon oxide film is accumulated by the plasma CVD method, and this is etched back by the anisotropic dry etching method, and thereby, a sidewall 11 is formed on the one side surface of the select gate electrode CG and the one side surface of the memory gate electrode MG. The spacer length of the sidewall 11 is, for example, around 60 nm. Thereby, it is possible to cover the exposed side surface of the gate dielectric 4 between the select gate electrode CG and the semiconductor substrate 1, and the exposed side surfaces of the dielectric films 6b and 6t and the charge storage layer CSL between the memory gate electrode MG and the semiconductor substrate 1 by the sidewall 11.

Next, with the sidewall 11 as a mask, n-type impurities, for example, arsenic and phosphor are ion implanted into the main surface of the semiconductor substrate 1, and thereby, an n⁺-type semiconductor region 2b is formed on the main surface of semiconductor substrate 1 in a self-aligning manner to the select gate electrode CG and the memory gate electrode MG. The ion implantation energy of this n-type impurity is, for example, around 50 keV, and the dose quantity thereof is, for example, around 4×10¹⁵cm⁻², the ion implantation energy of phosphor is, for example, around 40 keV, and the dose quantity thereof is, for example, around 5×10¹³cm⁻². Thereby, the drain region Drm comprising the n⁻-type semiconductor region 2ad and the semiconductor region 2b, and the source region Srm comprising the n⁻-type semiconductor region 2as of the n⁺-type semiconductor region 2b are formed.

Next, as shown in FIG. 21, on the top surface of the select gate electrode CG and the memory gate electrode MG, and on the top surface of the n⁺-type semiconductor region 2b, for example, a cobalt silicide (CoSi₂) layer 12 is formed by a self-aligning manner, for example, by the salicide (Self Align silicide) process. First, a cobalt film is accumulated on the main surface of semiconductor substrate 1 by the sputtering method. Then, by performing a heat treatment to the semiconductor substrate 1 by use of the RTA (Rapid Thermal Anneal) method, the cobalt film and a polycrystalline silicon film which comprises the select gate electrode CG and a polycrystalline silicon film comprising the memory gate electrode MG, and the cobalt film and a single crystal silicon comprising the semiconductor substrate 1 (n⁺-type semiconductor region 2b) are reacted and the cobalt silicide layer 12 is formed. Thereafter, the unreacted cobalt film is removed. By forming the cobalt silicide layer 12, it is possible to reduce the contact resistance between the cobalt silicide layer 12 and a plug and the like formed on the upper part thereof, and it is possible to reduce the resistance of the select gate electrode CG, the memory gate electrode MG, the source region Srm and the drain region Drm themselves.

Next, on the main surface of the semiconductor substrate 1, an interlayer dielectric 8 comprising, for example, a silicon nitride film 8a and a silicon oxide film 8b is formed by the CVD method. Then, a contact hole CNT is formed in the interlayer dielectric 8, and a plug PLG is formed in the contact hole CNT. The plug PLG has a relatively thin barrier film comprising, for example, a laminated film of titanium and titanium nitride, and a relatively thick conductive film comprising tungsten or aluminum or the like formed so as to be covered with the barrier film. Thereafter, on the interlayer dielectric 8, a first metal layer M1 comprising, for example, tungsten, aluminum or copper or the like is formed, and the memory cell MC1 shown in the above FIG. 1 is substantially completed. After this, through the process of manufacture of the normal semiconductor device, a semiconductor device is manufactured.

Thus, according to the first embodiment, the thickness (toxe) of the gate dielectric 4 under the gate longitudinal direction end of the select gate electrode CG is formed thicker than that (toxc) of the gate dielectric 4 under the gate longitudinal direction center, and the thickness of the lower layer dielectric film 6b that is positioned between the select gate electrode CG and the charge storage layer CSL and is nearest to the semiconductor substrate 1 is 1.5 times or below of the thickness of the lower layer dielectric film 6b positioned between the semiconductor substrate 1 and the charge storage layer CSL, thereby, it is possible to improve the disturb tolerance of the unselected memory cell at the time of program by the SSI method, without reducing a read current. Further, because the disturb tolerance of the unselected memory cell is improved, it is possible to reduce the area of the memory module.

### Second Embodiment

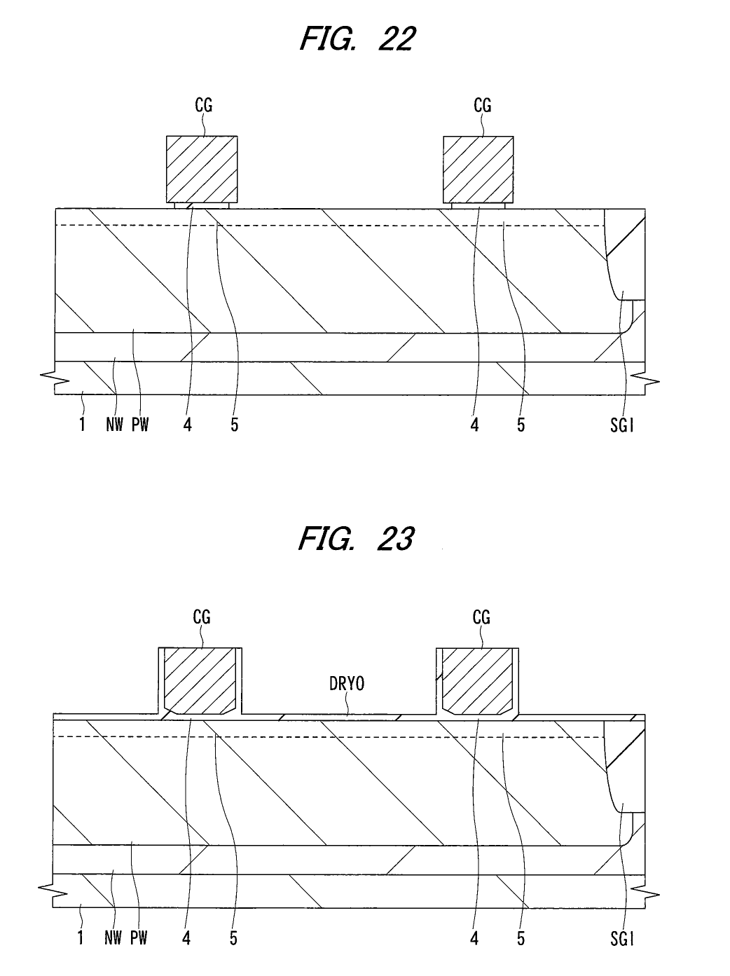

In a second embodiment, an example of the method of manufacturing a split gate type MONOS memory cell in which the formation method of the gate dielectric of nMIS for select is different from that in the first embodiment mentioned above will be explained. The method of manufacturing a split gate type MONOS memory cell by the second embodiment will be explained with reference to FIGS. 22 to 24. FIGS. 22 to 24 are cross sectional views showing the main part of a memory cell in the process of manufacture of the semiconductor device. The array structure and the operation conditions of a split gate type MONOS memory cell according to the second embodiment are same as those in the first embodiment mentioned above. Incidentally, because the manufacturing processes except the process of forming the gate dielectric of the nMIS for select is similar to the manufacturing process of the memory cell MC1 of the first embodiment mentioned above, the explanation thereof is omitted herein.

As explained with the above FIG. 13 of the first embodiment mentioned above, after the select gate electrode CG is formed, the exposed gate dielectric 4 is removed by, for example, a hydrofluoric acid water solution. At this time, as shown in FIG. 22, the gate dielectric 4 under the gate longitudinal direction end of the select gate electrode CG is side etched by a predetermined or specified distance. The distance removed from the gate longitudinal direction end of the select gate electrode CG is, for example, 3 to 20 nm.

Next, as shown in FIG. 23, by performing the dry oxidation processing or the ISSG oxidation processing to the semiconductor substrate 1, on the main surface of the semiconductor substrate 1, a silicon oxide film DRYO of the thickness of, for example, 4 nm is formed. The temperature of the dry oxidation processing is, for example, 800° C., and the temperature of the ISSG oxidation processing is, for example, 900° C. When the oxidation processing is performed in the state where the gate longitudinal direction end of the select gate electrode CG is exposed, even if the dry oxidation processing and the ISSG oxidation processing in which the bird's beak is hard to be formed in comparison with the wet oxidation processing are used, it is possible to form the bird's beak efficiently. Further, in the dry oxidation processing and the ISSG oxidation, the polycrystalline silicon film of the side of the select gate electrode CG is hard to be oxidized at an increased speed, and the silicon oxide film of the bell shape at the side of select gate electrode CG that is formed in the wet oxidation processing is not formed.

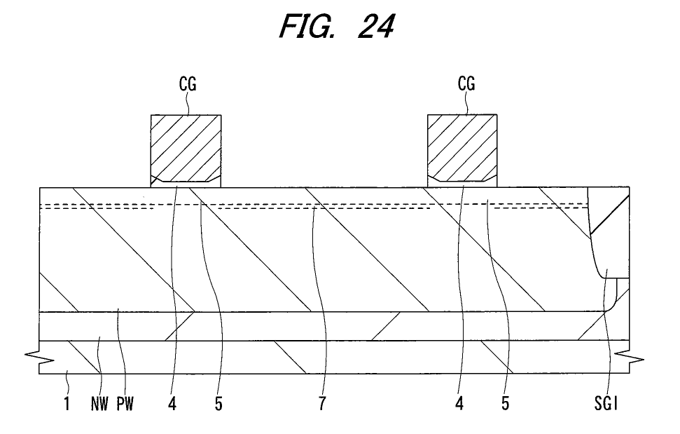

Next, as shown in FIG. 24, by the wet etching method using, for example, a hydrofluoric acid water solution, the silicon oxide film DRYO is etched. At this moment, the thickness of the silicon oxide film DRYO remaining in the lower part of the side of the select gate electrode CG is controlled so as to become equal to or below the thickness of the lower layer dielectric film 6b of the charge holding dielectric film to be formed later. The silicon oxide film DRYO may be etched until the lower part of the side of the select gate electrode CG is exposed. Thereafter, with the select gate electrode CG and the resist pattern as a mask, an n-type impurity, for example, arsenic or phosphor is ion implanted into the main surface of the semiconductor substrate 1, and thereby, an n-type semiconductor region 7 for the channel formation of the nMIS (Qnm) for memory is formed.

Thus, according to the second embodiment, because the bird's beak can be formed on the gate dielectric 4 under the gate longitudinal direction end of the select gate electrode CG, the same effect as that in the first embodiment mentioned above is provided. In addition, because the dry oxidation processing or the ISSG oxidation processing is used when the bird's beak is formed, the silicon oxide film of the bell shape is not formed like the first embodiment mentioned above at the side of the select gate electrode CG, therefore, it is possible to restrain the fluctuations of the shape and dimensions of the select gate electrode CG.

### Third Embodiment

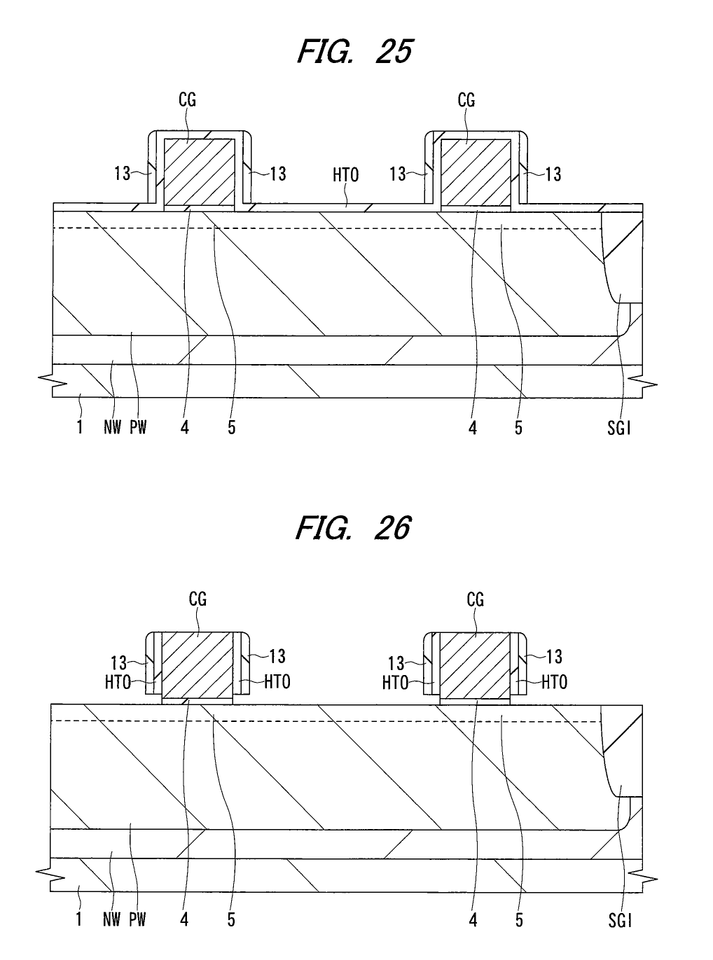

In a third embodiment, an example of the method of manufacturing a split gate type MONOS memory cell in which the formation method of the gate dielectric of the nMIS for select is different from that in the first and second embodiments mentioned above will be explained. The method of manufacturing the split gate type MONOS memory cell according to the third embodiment will be explained with reference to FIGS. 25 to 28. FIGS. 25 to 28 are cross sectional views showing the main part of a memory cell in the process of manufacture of the semiconductor device. The array structure and the operation conditions of a split gate type MONOS memory cell according to the third embodiment are same as those in the first embodiment mentioned above. Incidentally, because the manufacturing processes except the process of forming the gate dielectric of the nMIS for select is similar to the manufacturing process of the memory cell MC1 of the first embodiment mentioned above, the explanation thereof is omitted herein.

As explained with the above FIG. 13 of the first embodiment mentioned above, after the select gate electrode CG is formed, the exposed gate dielectric 4 is removed by, for example, a hydrofluoric acid water solution.

Next, as shown in FIG. 25, on the main surface of the semiconductor substrate 1, a high temperature silicon oxide film HTO of the thickness, for example, around 5 nm is formed by the CVD method. In the case to use the high temperature silicon oxide film HTO, there is an advantage that it is possible to remove the same by the wet etching later easily, but a silicon oxide film may be formed by the wet oxidation processing, the dry oxidation processing or the ISSG oxidation processing. Then, a silicon nitride film of the thickness, for example, 5 nm or more by the low voltage CVD method on the main surface of the semiconductor substrate 1 is formed, and this silicon nitride film is etched back by the anisotropic dry etching method, and thereby, a sidewall 13 is formed via the high temperature silicon oxide film HTO on both the sides of the select gate electrode CG.

Next, as shown in FIG. 26, the high temperature silicon oxide film HTO is etched until the gate dielectric 4 under the select gate electrode CG is exposed by the wet etching method using, for example, a hydrofluoric acid water solution.

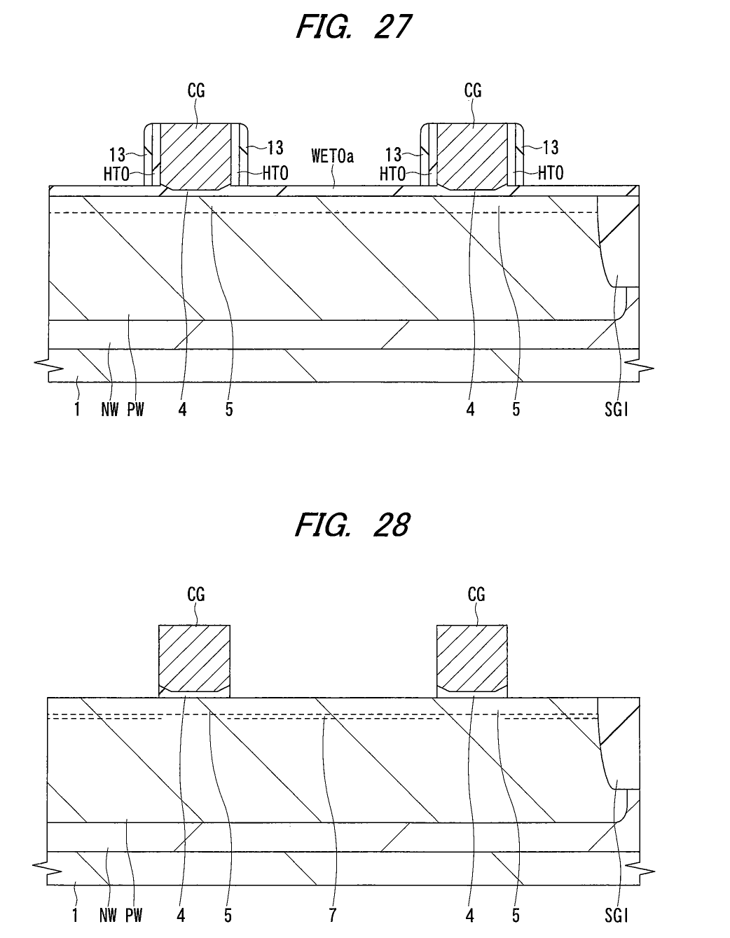

Next, as shown in FIG. 27, by performing the wet oxidation processing to the semiconductor substrate 1, a silicon oxide film WETOa of the thickness of, for example, around 4 nm is formed on the main surface of the semiconductor substrate 1. The temperature of the wet oxidation processing is, for example, 750° C. When the wet oxidation processing is performed, a bird's beak is formed in the end of the gate dielectric 4 positioned under the gate longitudinal direction end between the select gate electrode CG and the semiconductor substrate 1 (semiconductor region 5). In addition, because the wet oxidation processing is performed in the state where the side of the select gate electrode CG is in the condition not to be exposed, the polycrystalline silicon film at the side of the select gate electrode CG is not oxidized at an increased speed. In the place of the wet oxidation processing, the dry oxidation processing may be employed. In the dry oxidation processing, because the bird's beak is hard to be formed in comparison with the wet oxidation processing, the quantity of oxidation is increased than in the wet oxidation processing. For example, the dry oxidation processing is performed until the silicon oxide film WETOa of the thickness around 6 nm is formed on the main surface of the semiconductor substrate 1. The temperature of the dry oxidation processing is, for example, 800° C.

Next, as shown in FIG. 28, the sidewall 13 at the side of the select gate electrode CG is removed by use of, for example, heat phosphoric acid, and the silicon oxide film WETOa and the high temperature silicon oxide film HTO are removed by the wet etching method using a hydrofluoric acid water solution. Thereafter, with the select gate electrode CG and the resist pattern as a mask, an n-type impurity, for example, arsenic or phosphor is ion implanted into the main surface of the semiconductor substrate 1, and thereby, an n-type semiconductor region 7 for the channel formation of the nMIS (Qnm) for memory is formed.

Thus, according to the third embodiment, because the bird's beak can be formed onto the gate dielectric 4 under the gate longitudinal direction end of the select gate electrode CG, the same effect as the first embodiment mentioned above is provided. In addition, when the bird's beak is formed, the high temperature silicon oxide film HTO and the sidewall 13 made of a silicon nitride film are formed at the side surface of the select gate electrode CG, and the bell-shaped silicon oxide film is not formed at the side surface of the select gate electrode CG, and thereby, it is possible to restrain the fluctuations of the shape and dimensions of the select gate electrode CG.

### Fourth Embodiment

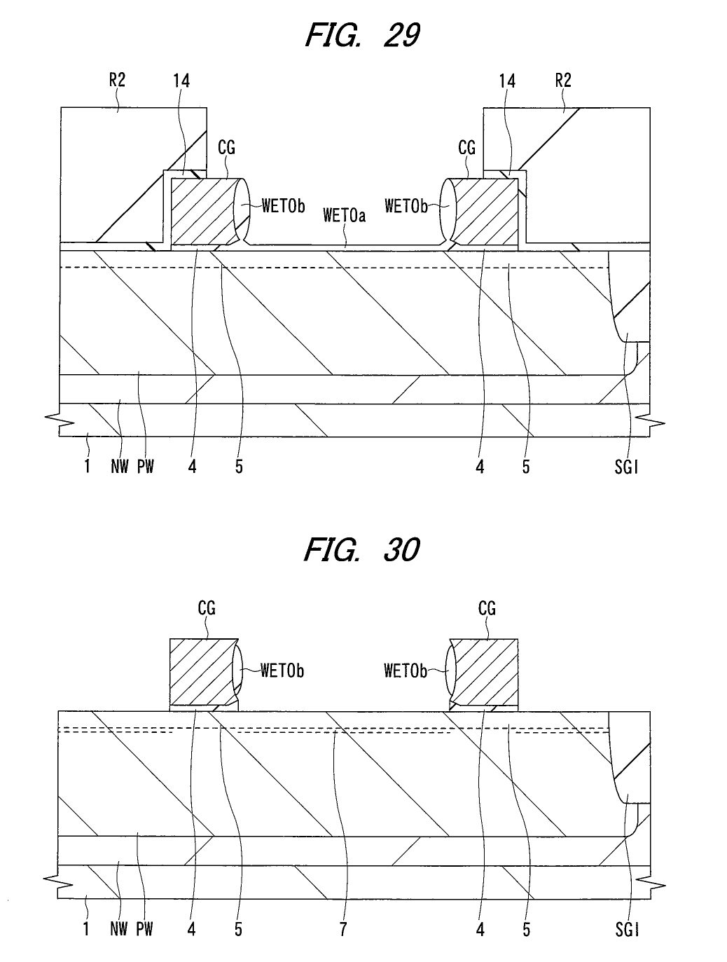

In a fourth embodiment, the bird's beak is formed only on the gate dielectric under the one end of the gate longitudinal direction of the select gate electrode CG of the nMIS for select. In the first to third embodiments mentioned above, the bird's beak is formed on the gate dielectric under both ends of the gate longitudinal direction of the select gate electrode, but even if the bird's beak is formed on only one side, it is possible to restrain the reduction of the read current, and to improve the disturb tolerance of the unselected memory cell. The method of manufacturing a split gate type MONOS memory cell according to the fourth embodiment will be explained with reference to FIGS. 29 and 30. FIGS. 29 and 30 are cross sectional views showing the main part of a memory cell in the process of manufacture of the semiconductor device. The array structure and the operation conditions of a split gate type MONOS memory cell according to the forth embodiment are same as those in the first embodiment mentioned above. Incidentally, because the manufacturing processes except the process of forming the gate dielectric of the nMIS (Qnc) for select is similar to the manufacturing process of the memory cell MC1 of the first embodiment mentioned above, the explanation thereof is omitted herein.

As explained with the above FIG. 14 of the first embodiment mentioned above, a silicon oxide film WETOa of the thickness of, for example, 4 nm is formed on the main surface of the semiconductor substrate 1, and a silicon oxide film WETOb of the bell shape is formed on the side of the select gate electrode CG, and the bird's beak is formed on the gate dielectric 4 under the gate longitudinal direction end between the select gate electrode CG and the semiconductor substrate 1 (semiconductor region 5).

Next, as shown in FIG. 29, a resist pattern to cover the drain region Drm side to form the bird's beak to the gate dielectric 4 of the nMIS (Qnc) for select is formed, and with this as a mask, the silicon oxide films WETOa and WETOb of the source region Srm side exposing from this are removed. Then, after the above resist pattern is removed, on the main surface of the semiconductor substrate 1 and after, for example, a silicon nitride film 14 is formed, a resist pattern R2 to cover the source region Srm on which the bird's beak is not formed is formed to the gate dielectric 4 of the nMIS (Qnc) for select.

Next, as shown in FIG. 30, by the wet etching method using, for example, a hydrofluoric acid water solution, and with the resist pattern R2 as a mask, the silicon nitride film 14 exposing from there is removed, and further, the silicon oxide films WETOa and WETOb are etched, while leaving a part of the silicon oxide film WETOb. At this moment, the thickness of the silicon oxide film WETOb to remain in the lower part of the side of the select gate electrode CG is controlled so as to become equal to or less than the thickness of the lower layer dielectric film 6b of a charge holding dielectric film to be formed later. The silicon oxide film WETOb may be etched until the lower part of the side of the select gate electrode CG is exposed.

Next, the resist pattern R2 is removed, and after the silicon nitride film 14 is removed, with the select gate electrode CG and the resist pattern as a mask, an n-type impurity, for example, arsenic or phosphor is ion implanted into the main surface of the semiconductor substrate 1, and thereby, an n-type semiconductor region 7 for the channel formation of the nMIS (Qnm) for memory is formed.

Thus, according to the fourth embodiment, because the bird's beak can be formed onto the gate dielectric 4 under the one end of the gate longitudinal direction of the select gate electrode CG, the same effect as the first embodiment mentioned above is provided. In addition, because the bell-shaped silicon oxide film is formed only at one side of the select gate electrode CG, and thereby, it is possible to restrain the fluctuations of the shape and dimensions of the select gate electrode CG more than the memory cell of the first embodiment mentioned above.

### Fifth Embodiment

In the first to fourth embodiments mentioned above, the method of manufacturing only a memory cell is described, but actually, the MIS of the peripheral circuit to be packaged together at the same time is also formed. In the MIS of the peripheral circuit, there are an MIS for core logic and a high withstand voltage MIS for high voltage control. Of these, the gate electrode of the MIS for core logic and the select gate electrode of the memory cell are not formed at the same time, and the select gate electrode of the memory cell is formed first, and then the gate electrode of the MIS for core logic is formed, and thereby it is possible to form the bird's beak on the gate dielectric of selection nMIS of the memory cell, without forming the bird's beak on the gate dielectric of the MIS for the core logic. If the bird's beak is not formed on the MIS for core logic, the ON current of the MIS for core logic does not decrease, and therefore, it is possible to secure the high speed operation of the core logic circuit. In addition, by forming the memory cell first, because heat load at the formation of the memory cell is applied before the MIS of the peripheral circuit is formed, it is possible to form the MIS of the peripheral circuit under the most suitable conditions without being influenced by the manufacturing process of the memory cell. Thereby, it is possible to form the MIS of the peripheral circuit suitable for the high speed operation.

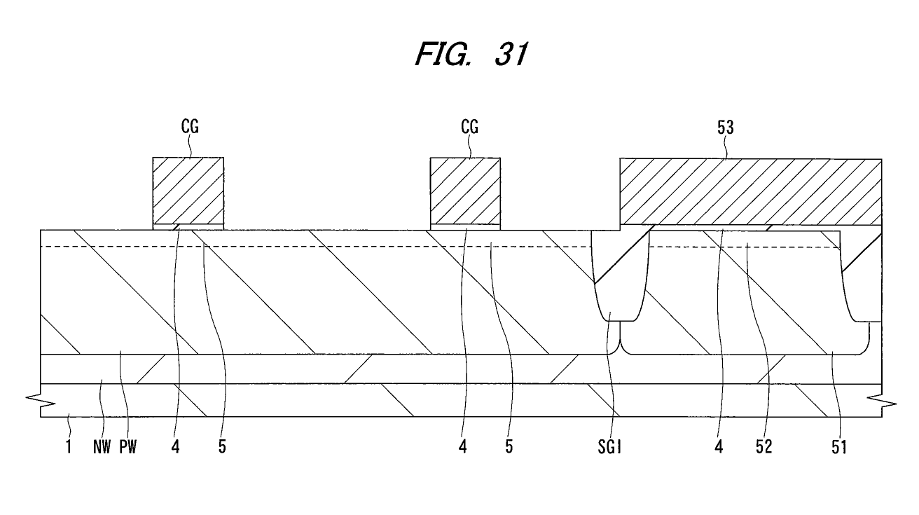

The method of manufacturing the nMIS of peripheral circuit and the split gate type MONOS memory cell according to the fifth embodiment will be explained with reference to FIGS. 31 to 34. FIGS. 31 to 34 are cross sectional views showing the main part of the nMIS of peripheral circuit and the memory cell in the process of manufacture of the semiconductor device. The array structure and the operation conditions of a split gate type MONOS memory cell according to the fifth embodiment are same as those in the first embodiment mentioned above. Incidentally, because the manufacturing processes of the memory cell is same as those of the first embodiment mentioned above, therefore, detailed explanation thereof is omitted herein.

First, as shown in FIG. 31, in the same manner as in the first embodiment mentioned above (refer to the above FIG. 12), an element isolation region SGI is formed in the main surface of the semiconductor substrate 1, and embedded n well NW and p well PW, 51 are formed in the memory cell region and the peripheral circuit region. Thereafter, a semiconductor region 5 for the channel formation of the nMIS (Qnc) for select is formed in the memory cell region, and a semiconductor region 52 for the channel formation of the nMIS of the core logic is formed in the peripheral circuit region.

Next, after the gate dielectric 4 is formed on the main surface of the semiconductor substrate 1, a first conductive film 53 comprising a polycrystalline silicon film is accumulated on the main surface of the semiconductor substrate 1. Thereafter, with the resist pattern as a mask, the first conductive film 53 is processed, and thereby, a select gate electrode CG is formed in the memory cell region. Although the gate electrode of the nMIS for core logic may be formed in the peripheral circuit region at the same time, but herein, the first conductive film 53 of the peripheral circuit region is covered with the resist pattern, and the gate electrode of the nMIS for core logic is not processed. Thereafter, the exposed gate dielectric 4 is removed by, for example, a hydrofluoric acid water solution.

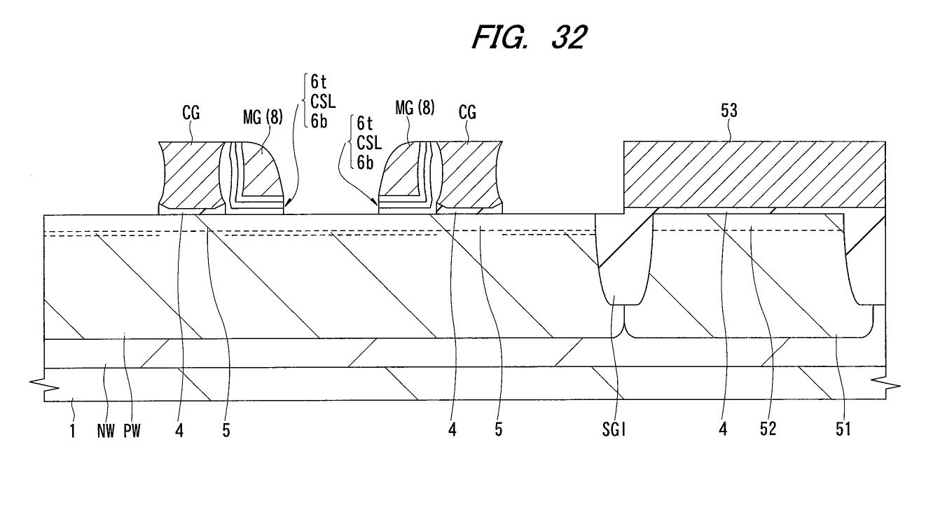

Next, as shown in FIG. 32, in the same manner as the first embodiment mentioned above (refer to the above FIGS. 14 to 19), in the memory cell region, a bird's beak is formed to the gate dielectric 4 under the gate longitudinal direction end of the select gate electrode CG, and charge holding dielectric films (the dielectric films 6b and 6t and the charge storage layer CSL) are formed, and the memory gate electrode MG is formed. Meanwhile, in the peripheral circuit region, the first conductive film 53 is not processed.

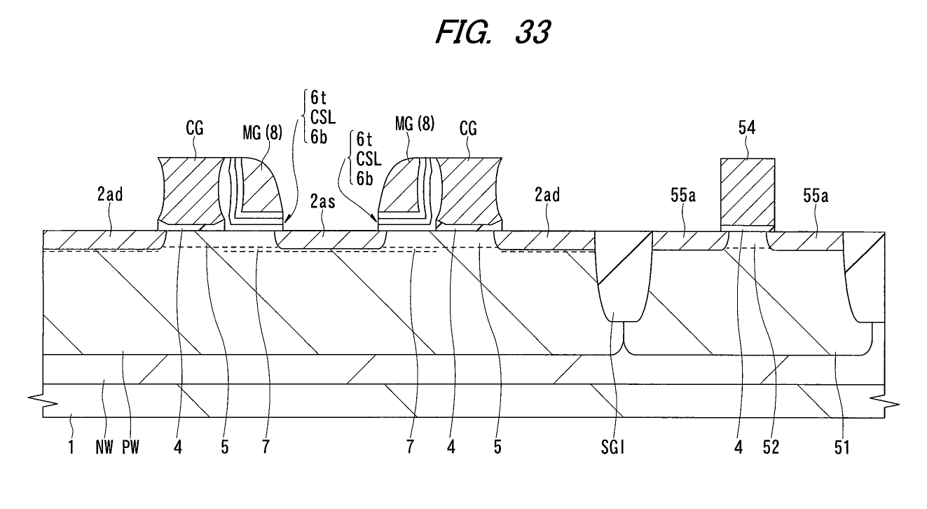

Next, as shown in FIG. 33, with a resist pattern as a mask, the first conductive film 53 of the peripheral circuit region is processed by the dry etching method, and a gate electrode 54 of the nMIS for the core logic is formed. At this time, the memory cell region is covered with the resist pattern. Then, with the gate electrode 54 as a mask, n-type impurity is ion implanted into the main surface of semiconductor substrate 1, and thereby an n⁻-type semiconductor region 55a is formed on the main surface of semiconductor substrate 1 in a self-aligning manner to the gate electrode 54.

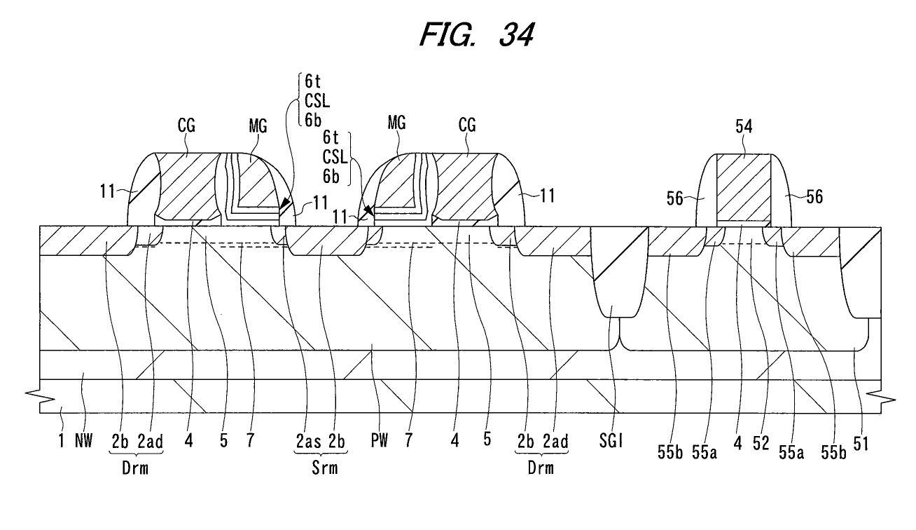

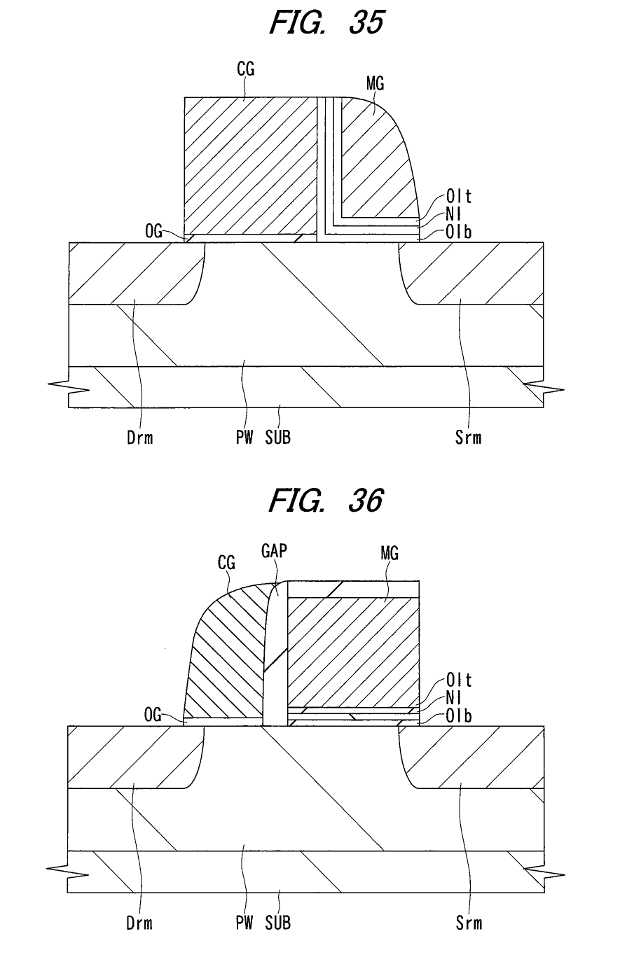

Next, as shown in FIG. 34, on the main surface of the semiconductor substrate 1, a dielectric film comprising, for example, a silicon oxide film is accumulated by the plasma CVD method, and this is etched back by the anisotropic dry etching method, and thereby a sidewall 11 is formed in the one side surface of the select gate electrode CG of the memory cell region and the one side surface of the memory gate electrode MG, and a sidewall 56 is formed on both sides of the gate electrode 54 of the nMIS for core logic in the peripheral circuit region at the same time. Thereafter, in the memory cell region, with the sidewall 11 as a mask, n-type impurity is ion implanted into the main surface of the semiconductor substrate 1, and thereby, an n⁺-type semiconductor region 2b is formed on the main surface of the semiconductor substrate 1 in the self-aligning manner to the select gate electrode CG and the memory gate electrode MG. Thereby, the drain region Drm comprising the n⁻-type semiconductor region 2ad and the n⁺-type semiconductor region 2b, and the source region Srm comprising the n⁻-type semiconductor region 2as and the n⁺-type semiconductor region 2b are formed. Further, in the peripheral circuit region, with the sidewall 56 as a mask, an n-type impurity is ion implanted into the main surface of the semiconductor substrate 1, and thereby, an n⁺-type semiconductor region 55b is formed on the main surface of the semiconductor substrate 1 in the self-aligning manner to the gate electrode 54. Thereby, the drain/source comprising the n⁻-type semiconductor region 55a and the n⁺-type semiconductor region 55b are formed. Thereafter, for example, in the same manner as in the first embodiment mentioned above (refer to the above FIG. 21), wires and the like are formed.

Thus, according to the fifth embodiment, after the memory cell is formed, the MIS of the peripheral circuit is formed, and thereby, it is possible to manufacture the semiconductor device in which the nMIS (Qnc) for select of the memory cell where the bird's beak is formed in the gate dielectric 4, and the MIS of the peripheral circuit where the bird's beak is not formed in the gate dielectric are packaged on a same substrate.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the above embodiments, as an charge holding dielectric film of the memory cell, a charge storage layer comprising a silicon nitride film is used, but in the place of the silicon nitride film, a charge-trapping dielectric film such as an acid silicon nitride film, a tantalum oxide film, an aluminum oxide film or the like may be used. In addition, as a charge storage layer, conductive materials such as polycrystalline silicon films or the like or fine particles (dots) comprising conductive materials may be employed.

The present invention may be applied to a semiconductor memory device having a nonvolatile memory cell to store a charge into a dielectric film such as a nitride film.

What is claimed is:

1. A semiconductor memory device comprising nonvolatile memory cells including a first field effect transistor in a first region of the main surface of a semiconductor substrate, and a second field effect transistor which is adjacent to the first field effect transistor in a second region, wherein
a first gate electrode of the first field effect transistor formed in the first region, a second gate electrode of the second field effect transistor formed in the second region, a first gate dielectric formed between the semiconductor substrate and the first gate electrode, a charge storage layer formed between the semiconductor substrate and the second gate electrode and between the first gate electrode and the second gate electrode, and a first dielectric film formed between the semiconductor substrate and the charge storage layer and between the first gate electrode and the charge storage layer are arranged,
the thickness of the first gate dielectric under the gate longitudinal direction end of the first gate electrode is thicker than that of the first gate dielectric under the gate longitudinal direction center of the first gate electrode, and the thickness of the first dielectric film that is positioned between the first gate electrode and the charge storage layer and is nearest to the semiconductor substrate, is 1.5 times or below of the thickness of the first dielectric film between the semiconductor substrate and the charge storage layer.

2. The semiconductor memory device according to claim 1, wherein the thickness of the first gate dielectric under the gate longitudinal direction end of the first gate electrode is thicker by 0.5 nm or more than that of the first gate dielectric under the gate longitudinal direction center of the first gate electrode.

3. The semiconductor memory device according to claim 1, further comprising
a third field effect transistor formed in a third region of the main surface of the semiconductor substrate for performing a logic operation,
a third gate electrode of the third field effect transistor formed in the third region, and
a second gate dielectric formed between the semiconductor substrate and the third gate electrode are arranged, and wherein
the difference between the thickness of the second gate dielectric under the gate longitudinal direction end of the third gate electrode and the thickness of the second gate dielectric under the gate longitudinal direction center of the third above gate electrode is 0.5 nm or below.

4. The semiconductor memory device according to claim 1, wherein the thickness of the first gate dielectric under one gate longitudinal direction end of the first gate electrode is thicker than that of the first gate dielectric under the gate longitudinal direction center of the first gate electrode.

5. The semiconductor memory device according to claim 1, wherein the charge storage layer is a silicon nitride film, an silicon oxynitride film, a tantalum oxide film or an aluminum oxide film.

6. The semiconductor memory device according to claim 1, wherein the first dielectric film is a silicon oxide film.

7. The semiconductor memory device according to claim 1, wherein a second dielectric film is arranged between the second gate electrode and the charge storage layer.

8. The semiconductor memory device according to claim 7, wherein the second dielectric film is a silicon oxide film, a dielectric film in which a silicon nitride film is inserted in between silicon oxide films, or a dielectric film in which an amorphous silicon film is inserted in between silicon oxide films.

9. The semiconductor memory device according to claim 1, wherein information is written by injecting hot electrons into the charge storage layer by an SSI method.

10. The semiconductor memory device according to claim 1, wherein information is erased by injecting hot holes into the charge storage layer by a BTBT phenomenon.

11. A method of manufacturing a semiconductor memory device for forming nonvolatile memory cells including a first field effect transistor in a first region of the main surface of a semiconductor substrate, and a second field effect transistor which is adjacent to the first field effect transistor in a second region, the method comprising the steps of:
(a) forming a first gate dielectric in the main surface of the semiconductor substrate in the first region;
(b) forming the first gate electrode of the first field effect transistor comprising the first conductive film via the first gate dielectric in the first region, after forming the first conductive film on the main surface of the semiconductor substrate;
(c) removing the first gate dielectric of other regions than the first gate dielectric under the first gate electrode;
(d) performing a first oxidation processing to the semiconductor substrate, and making the thickness of the first gate dielectric under the gate longitudinal direction end of the first gate electrode thicker than that of the first gate dielectric under the gate longitudinal direction center of the first gate electrode;
(e) performing a second oxidation processing to the semiconductor substrate by removing the whole or part of an oxide film formed by the first oxidation processing, after the step (d), and thereby forming a first dielectric film;
(f) forming a charge storage layer on the first dielectric film, after the step (e);
(g) forming the second conductive film on the main surface of the semiconductor substrate after the step (f), processing the second conductive film by anisotropic etching, and thereby forming sidewalls comprising the second conductive films on both of the sides of the first gate electrode;
(h) removing the sidewall formed on one side of the first gate electrode, and making the sidewall remaining on the other side of the first gate electrode a second gate electrode; and
(i) removing the first dielectric film and the charge storage layer of other regions than the first dielectric film and the charge storage layer formed between the first gate electrode and the second gate electrode, and in a second region.

12. The method of manufacturing a semiconductor memory device according to claim 11, wherein, in the step (e), the first dielectric film is formed so that the thickness of the first dielectric film that is positioned between the first gate electrode and the charge storage layer and is nearest to the semiconductor substrate, is 1.5 times or below of that of the first dielectric film between the semiconductor substrate and the charge storage layer.

13. The method of manufacturing a semiconductor memory device according to claim 11, wherein the thickness of the first gate dielectric under the gate longitudinal direction end of the first gate electrode is formed thicker by 0.5 nm or more than that of the first gate dielectric under the gate longitudinal direction center of the first gate electrode.

14. The method of manufacturing a semiconductor memory device according to claim 11, further comprising the following step between the step (f) and the step (g):
(j) forming a second dielectric film on the charge storage layer.

15. The method of manufacturing a semiconductor memory device according to claim 11, wherein the second oxidation processing is performed to the semiconductor substrate by performing ISSG oxidation processing.

16. The method of manufacturing a semiconductor memory device according to claim 11, wherein the first oxidation processing is wet oxidation processing.

17. The method of manufacturing a semiconductor memory device according to claim 11, wherein the first oxidation processing is dry oxidation processing.

18. The method of manufacturing a semiconductor memory device according to claim 17, wherein, in the step (c), the first gate dielectric under the gate longitudinal direction end of the first gate electrode is further etched by 3 to 20 nm from the end of the first gate electrode.

19. The method of manufacturing a semiconductor memory device according to claim 11, wherein the step (d) further including the steps of:
(d1) forming a third dielectric film on the main surface of the semiconductor substrate;
(d2) forming sidewalls comprising a fourth dielectric film via the third dielectric film on the sides of the first gate electrode;
(d3) removing the third dielectric film, until the first gate dielectric under the first gate electrode is exposed; and
(d4) performing dry oxidation processing to the semiconductor substrate, and forming the thickness of the first gate dielectric under the gate longitudinal direction end of the first gate electrode thicker than that of the first gate dielectric under the gate longitudinal direction center of the first gate electrode, and further,
the step (e) including a step of
(e1) removing the third dielectric film of other regions than the first gate dielectric under the first gate electrode, the sidewalls, and the oxide film formed by the dry oxidation processing.
